(19) United States
(12) Patent Application Publication
(10) Pub. No.: US 2024/0205563 A1
(43) Pub. Date: Jun. 20, 2024

(54) PERIPHERAL CIRCUITS FOR PROCESSING IN-PIXEL

(71) Applicant: University of Southern California, Los Angeles, CA (US)

(72) Inventors: Peter Beerel, Los Angeles, CA (US); Gourav Datta, Los Angeles, CA (US); Ajey P. Jacob, Watervliet, NY (US); Akhilesh Jaiswal, Madison, WI (US); Zihan Yin, Los Angeles, CA (US)

(21) Appl. No.: 18/545,859

(22) Filed: Dec. 19, 2023

Related U.S. Application Data
(60) Provisional application No. 63/433,592, filed on Dec. 19, 2022.

(51) Int. Cl. H04N 25/77; H01L 23/00; H01L 27/146

(52) U.S. Cl. CPC H04N 25/77; H01L 24/16; H01L 27/14634; H01L 2224/16145; H01L 2224/16225

(57) ABSTRACT

Provided is an integrated circuit comprising: a sensor structure; a set of weighting elements, each configured to weight an output of the sensor structure; and an output element, the output element configured to collect weighted outputs of the set of weighting elements.

### CROSS-REFERENCE TO RELATED APPLICATIONS

This application claims the benefit of U.S. Provisional Pat. App. 63/433,592, titled PERIPHERAL CIRCUITS FOR PROCESSING IN-PIXEL, filed 19 Dec. 2022, the entire content of each of which is hereby incorporated by reference.

### GOVERNMENT LICENSE RIGHTS

This invention was made with government support under grant number HR00112190120 awarded by the Defense Advanced Research Projects Agency (DARPA). The government has certain rights in the invention.

### BACKGROUND

Traditionally, pixel (e.g., photodiodes), memory (e.g., static random-access memory (SRAM)/dynamic random-access memory (DRAM)) and/or processing elements are separate entities in a CMOS Image Sensor (CIS), which may degrade size, weight, and power (SWaP) and create bandwidth, data processing, and/or switching speed (e.g., as measured by energy-delay product (EDP) or other metric) bottlenecks. As pixels may be separate from memory and processing, the data acquired by a sensor may be transmitted or transferred to a remote computing entity (e.g., chip, computer, server, etc.) for calculations (including dot product calculation, for example), analysis, and decision making, including for AI-based processing. The physical segregation of sensing (at the photodiode) from processing (at the processing element) leads to multiple data and data transfer bottlenecks which limit throughput, increase energy consumption for data transfer, require high amounts of wired or wireless bandwidth and levels of connectivity for continuous or near continuous data transfer, and generate security concerns. Artificial intelligence (AI) and/or other data analytics and data science techniques—which are often server (or cloud) centric—may also require preprocessing, computing, packaging, or transmission of sensor data to be performed by computing entities, which can be hampered by separation into disparate elements. High resolution images, which may be desired for AI inferences, may increase the load on data transference processes.

### SUMMARY

The following is a non-exhaustive list of some aspects of the present techniques. These and other aspects are described in the following disclosure.

Some aspects include integration of a parallel transistor layer into a photosensor, where transistors in the parallel layer may be connected in series with and used to weight the output of pixels of the photosensor.

Some aspects include weighting output of the pixels based on weights corresponding to a layer of a convolutional neural network (CNN).

Some aspects include weighting outputs of the pixels processed by correlated double sampling (CDS).

Some aspects include dot product summation of weighted output of the pixels.

Some aspects include dot product summation of positive weighted output of the pixels, which may correspond to a select line representing positive weightings, and dot product summation of negative weighted output of the pixels, which may correspond to a select line representing negative weightings.

Some aspects include determination of a difference between the dot product summation of the positive weighted output of the pixels and the dot product summation of the negative weighted output of the pixels.

Some aspects include rectified linear unit (ReLU) or quasi-ReLU operation, which may clip the difference between the dot product summation of the positive weighted output of the pixels and the dot product summation of the negative weighted output of the pixels to a zero or positive value.

Some aspects may include a resent phase.

Some aspects may include a multi-pixel convolution phase.

Some aspects may include a ReLU operation, which may be performed by a counter.

Some aspects may include one or more quantization operations.

Some aspects include fabricating one or more circuits to perform one or more operations including the above-mentioned aspects.

Some aspects include a tangible, non-transitory, machine-readable medium storing instructions that when executed by a data processing apparatus cause the data processing apparatus to perform one or more operations including the above-mentioned aspects.

Some aspects include a system, including: one or more processors; and memory storing instructions that when executed by the processors cause the processors to effectuate one or more operations of the above-mentioned aspects.

### BRIEF DESCRIPTION OF THE DRAWINGS

The above-mentioned aspects and other aspects of the present techniques will be better understood when the present application is read in view of the following figures in which like numbers indicate similar or identical elements:

FIG. 1 depicts a schematic representation of an example embodiment for processing-in-pixel-in-memory (P2M), in accordance with one or more embodiments;

FIG. 2(a) depicts an example circuit techniques for mapping of computational aspects of the first few layers of a CNN layer within a CIS pixel array, in accordance with one or more embodiment;

FIG. 2(b) depicts a schematic representation of summation over multiple pixels for a P2M scheme, in accordance with one or more embodiments;

FIG. 2(c) depicts a schematic representation of a peripheral analog to digital converter (ADC) with digital correlated double sampling (CDS), in accordance with one or more embodiments;

FIG. 3(a) depicts a graph displaying simulated pixel output voltage as a function of weight (e.g., transistor width) and input activation (e.g., normalized photo-diode current), in accordance with one or more embodiment;

FIG. 3(b) depicts a scatter plot comparing pixel output voltage to an ideal multiplication value of weights by input activation (e.g., Normalized W×I), in accordance with one or more embodiments;

FIG. 3(c) depicts a graph displaying an analog convolution output voltage for the simulation of FIG. 3(a) versus an ideal normalized convolution value when 75 pixels are activated simultaneously, in accordance with one or more embodiments;

FIG. 4(a) depicts a graph of a typical timing waveform, showing double sampling (e.g., one sampling for positive weights and one sampling for negative weights), in accordance with one or more embodiments;

FIG. 4(b) depicts a graph of a typical timing waveform for a SS-ADC, showing comparator output, counter enable (e.g., trigger), ram generator output, and counter clock (e.g., counter), in accordance with one or more embodiments;

FIG. 5 is a schematic representation of a heterogeneously integrated system in the P2M paradigm, built on a backside illuminated CMOS image sensor (Bi-CIS), in accordance with one or more embodiments;

FIG. 6 is a schematic representation of algorithm-circuit co-design to optimize performance and energy-efficiency of vision workloads, in accordance with one or more embodiments;

FIG. 7(a) is a graph of the effect of quantization on in-pixel output activations, in accordance with one or more embodiments;

FIG. 7(b) is a graph of the effect of the number of channels in the first convolutional layer for different kernel sizes and strides on test accuracy, in accordance with one or more embodiments;

FIG. 8(a) is a graph comparing normalized total, sensing, and SoC energy costs between P2M and baseline models, in accordance with one or more embodiments;

FIG. 8(b) is a graph comparing normalized total, sensing, and SoC energy costs between P2M and baseline models, in accordance with one or more embodiments;

FIG. 9 is a schematic representation of an array level structure for analog dot products using multi-bit, multi-kernels, in accordance with one or more embodiments;

FIG. 10 is a schematic representation of an example integration scheme, according to some embodiments.

FIG. 11 is a schematic representation of an example monolithic integration scheme; according to some embodiments;

FIG. 12 is a schematic representation of an example integration scheme; according to some embodiments;

FIG. 13 is a schematic diagram that illustrates an example processing in pixel circuit, in accordance with one or more embodiments;

FIG. 14 is a schematic diagram that illustrates an example processing in pixel circuit in relation to a neural network, in accordance with one or more embodiments; and

FIG. 15 is a system diagram that illustrates an example computing system comprising processing in pixel, in accordance with one or more embodiments.

While the present techniques are susceptible to various modifications and alternative forms, specific embodiments thereof are shown by way of example in the drawings and will herein be described in detail. The drawings may not be to scale. It should be understood, however, that the drawings and detailed description thereto are not intended to limit the present techniques to the particular form disclosed, but to the contrary, the intention is to cover all modifications, equivalents, and alternatives falling within the spirit and scope of the present techniques as defined by the appended claims.

### DETAILED DESCRIPTION

To mitigate the problems described herein, the inventors had to both invent solutions and, in some cases just as importantly, recognize problems overlooked (or not yet foreseen) by others in the fields of machine learning and computer science. Indeed, the inventors wish to emphasize the difficulty of recognizing those problems that are nascent and will become much more apparent in the future should trends in industry continue as the inventors expect. Further, because multiple problems are addressed, it should be understood that some embodiments are problem-specific, and not all embodiments address every problem with traditional systems described herein or provide every benefit described herein. That said, improvements that solve various permutations of these problems are described below.

The description that follows includes example systems, methods, techniques, and operation flows that illustrate aspects of the disclosure. However, the disclosure may be practiced without these specific details. For example, this disclosure refers to specific types of computational circuits (e.g., dot product, correlated double sampling (CDS), single-slope analog to digital converters (ADCs) (SS-ADCs), comparators, etc.), specific types of processing operations (e.g., multi-bit convolution, batch normalization (BN), rectified linear units (ReLU), etc.) and specific types of machine learning models (convolutional neural networks (CNNs), encoder, autoencoders, etc.) in illustrative examples. Aspects of this disclosure can instead be practiced with other or additional types of circuits, processing operations and machine learning models. Additionally, aspects of this disclosure can be practiced with other types of photosensors or sensors which are not photosensors. Further, well-known structures, components, instruction instances, protocols, and techniques have not been shown in detail to not obfuscate the description.

Signals from photodetectors and photosensors, such as photodiodes, may be analyzed by AI-based algorithms, for example for motion detection, facial recognition, threat recognition, etc. Signals, such as corresponding to high-resolution images, may benefit from processing, such as application of pre-processing or application of one or more layers of a machine learning model, before the data is transferred out of the image sensor—that is before the data is fully analyzed, uploaded for analysis, or even displayed. Processing may include pre-processing, compression, application of one or more layers of a machine learning model (e.g., CNN), comparator operations, rectification, etc. Integration of analog and/or digital computing ability into circuitry within the pixel may allow memory elements, processing elements, and sensors elements to be combined in order to reduce the number of total elements, provide embedded processing at the pixel (which may increase processing speed and reduce data transfer requirements), and reduce the distance between components for image sensors to reduce memory and computing power consumption. Adding computational elements to each pixel or to groups of pixels may generate parallel computational ability and computational power. Additional transistors may be added to each pixel, which may function as built-in weightings, which may allow weighting of values output by each pixel, such as corresponding to weighting of nodes in one or more layer of a CNN. Additional circuit elements, which may allow summation, weighting, etc. at the sensor level, may be integrated monolithically—on the same chips which contains the pixels or photodiodes—or heterogeneously, such as by using vias and complementary circuit design. Multi-bit, multi-kernel, and multi-channel memory and logic may therefore be embedded into pixel architecture. Pixel circuitry may be augmented with additional types of memory and logical elements, including multiple types of memory and computational elements within a single pixel, photosensor, or sensor.

Some embodiments may implement the techniques described in Datta, G., Kundu, S., Yin, Z. et al. A processing-in-pixel-in-memory paradigm for resource-constrained TinyML applications. Sci Rep 12, 14396 (2022). https://doi.org/10.1038/s41598-022-17934-1, the contents of which are hereby incorporated by reference in their entirety.

Some embodiments may implement the techniques and/or devices (in part or in full) described in U.S. Provisional Application 63/302,849, titled “Embedded ROM-based Multi-Bit, Multi-Kernel, Multi-Channel Weights in Individual Pixels for Enabling In-Pixel Intelligent Computing,” filed 25 Jan. 2022, the contents of which are hereby incorporated by reference in their entirety.

Some embodiments may implement the techniques and/or devices (in part or in full) described in PCT Patent Application PCT/US2023/011531, titled “Embedded ROM-based Multi-Bit, Multi-Kernel, Multi-Channel Weights in Individual Pixels for Enabling In-Pixel Intelligent Computing,” filed 25 Jan. 2023, the contents of which are hereby incorporated by reference in their entirety.

Example embodiments may include monolithic integration of sensors. Monolithic integration may involve CMOS image sensors (including other visible and near visible light sensors), ultraviolet sensors, infrared sensors, terahertz electromagnetic radiation sensors, etc. These sensors may be integrated with memory—for example eDRAM and ROM—where the memory is of the same technology node as the sensor, where the technology node corresponds approximately to a size of the geometry of the transistors (but not necessarily to a specific transistor dimension) which make up the sensor, etc. The light capturing photodiodes in the sensor and memory elements may be further integrated with logic, which may or may not be of the same technology node as the sensor and memory. The logic may be analog. In some embodiments, the logic may multiply or accumulate signals (or approximate multiplication or summation), such as for neural network computing applications.

Example embodiments may also include heterogeneous integration of sensors, such as CMOS image sensors (and other visible and near visible light sensors), ultraviolet sensors, infrared sensors, terahertz electromagnetic radiation sensors, etc. These sensors may be integrated with memory and/or logic—e.g., eDRAM and ROM, comparators, ADCs—where the memory and/or logic can be of a different technology node from the sensor. For example, the memory may be of a smaller technology node than the sensor, or of a large technology node than the sensor. The sensor and memory may be further integrated with logic, which may be of the same technology node as either the sensor or memory or which can be of another technology node. The logic may be analog and/or digital. In some embodiments, the logic may multiply or accumulate (e.g., MAC) signals (or approximate multiplication or summation), such as for neural network computing applications. In some embodiments, the logic may weight signals, such as based on weighting of nodes in one or more machine learning model layer, before or after multiplication or accumulation of signals.

Example embodiments may include a method of mapping one or more layers of a neural network onto pixels of sensors. Example embodiments may include mapping a neural network onto image sensors by configuring parallel computing elements within multiple pixels. Example embodiments may include mapping weights of a neural network onto image sensors by configuring parallel weighting, such as by using parallel transistors having multiple widths or W/L ratios, to weight output of pixels. Example embodiments may include photosensors (e.g., of each pixel) connected in series to multiple parallel weighting elements, e.g., weighting transistors, which may be turned on by independent select lines. Example embodiments may include select lines for positive weighting and select lines for negative weighting, where positive weightings and negative weightings may be summed separately. Example embodiments may include noise reducing circuitry, such as CDS circuitry. Example embodiments may include analog-to-digital conversion circuitry, such as ADC, and digital-to-analog circuitry, DAC. Example embodiments may include single slope ADCs (SS-ADCs), or other circuitry (including counters) that may digitize output. Example embodiments may include difference determination circuitry. Example embodiments may include clipping or rectification circuitry, including ReLUs.

Example embodiments may include one or more methods of analog computing, including for in-sensor neural network applications.

Example embodiments may include a pixel circuit comprising an image sensor and memory and/or logic. Example embodiments may further include a pixel array consisting of an image sensor and memory and/or logic. Example embodiments may further include a pixel array consisting of multiple image sensors and memory and/or logic.

Example embodiments include multi-functional read circuits for analog computing. Example embodiments may include read circuits for analog circuits, but may also include read circuits for digital circuits.

Example embodiments may include trans-impedance amplifiers for signal processing. Example embodiments may include neural network neurons comprising trans-impedance amplifiers.

Incorporation of memory and/or logic within sensor architecture may increase power efficiency, increases performance, and increases density per unit area. Both monolithic and heterogeneous integration of sensors, memory, and/or logic, may create in-pixel computing elements in space which may have previously been wasted or empty (e.g., peripheral). In-pixel circuit elements may enable massively parallel analog computing, where each sensor pixel and its memory and/or logic may cause processing in parallel. In-pixel circuit elements may enable weighting of pixel outputs. Through appropriate architecture design, neural network processing and various computational elements may be mapped onto outputs of the sensors themselves for quick or improved speed in analysis and decision making, such as for application of AI-based inference or detection engines. Data density and/or bottleneck reduction may be accomplished via in-pixel or on-pixel processing, which may reduce the amount of data requiring transfer to other computation elements without sacrificing accuracy.

Example embodiments for multi-bit, multi-kernel, and multi-channel memory and/or logic embedded pixels are depicted in the accompanying figures and described herein. In an example, a photo diode, photosensor, or other sensor may be connected with a gate of a first transistor, and the photodiode-gated first transistor (hereinafter “amplifying transistor”) may be connected to a set of parallel transistors (e.g., weighting transistors W₁ through Wₙ) where the parallel transistors act as a source or drain for the amplifying transistor and may applying weightings to the output of the amplifying transistors. It should be understood that a photodiode may be described or depicted in an example embodiment, but that the photodiode can instead be a photosensor or any other appropriate type of sensor. In some embodiments the photodiode may be operably or electrically coupled to a first memory element or logical element (including a reset element) before being coupled to the sensor-gate. As an example, a photodiode may be coupled in series with a storage device, where the storage device, which may be a transistor, may be configured to store a written value fixed during manufacturing or a volatile value which may be written and/or overwritten during operation. This is not an exhaustive list of the possible memory and/or logical element configurations which can contain or be coupled with the photodiode.

In some embodiments, the parallel transistors may be connected to a source or a drain of the amplifying transistor. Hereinafter, any mention of a transistor source should be understood to be encompass instead a transistor drain and likewise any mention of a transistor drain should be understood to encompass use of a transistor source, as transistors may be symmetric or may be designed with various source-drain properties. The parallel transistors (e.g., weighting transistors) may in turn each be controlled by gates connected to one of a set of parallel input lines (e.g., input lines P₁ through P_{N}). Each of the parallel transistors may have different physical or electrical characteristics or dimensions, such as width, W/L (width to length ratio), threshold voltage Vₜ, output characteristics, transfer characteristics, etc. In some example embodiments, the parallel input lines may instead be parallel output lines. One or more of the parallel input lines may be activated or charged at a time, which in turn may gate (e.g., turn on or off) one or more of the parallel transistors. For example, both transistor N (with a W/Lₙ) and a transistors M (with a W/Lₘ) can be turned on during a time period, or one transistor may be active at a time, or no transistors may be turned on. The parallel transistors may be floating gate transistors, fin field-effect transistor (finFET), charge trapped transistor (CTT), or any other appropriate geometry or arrangement of transistors. In some examples, each of the parallel input lines may correspond to a specific kernel or a specific channel, which may correspond to a specific neural network layer.

The parallel transistors (e.g., weighting transistors) may in turn each be connected by sources (e.g., or alternatively by drains) to a select line, which may provide a drain (or source voltage) such as V_{DD}. The select line may instead be a set of select lines, such as V_{DD} for positive weights and V_{DD} for negative weights. The select lines may include more voltage supplies to the parallel transistors, for example such as high and low V_{DD} for both positive and/or negative weights.

The total drain current of the parallel transistors (e.g., that current output amplifying transistors), which may be the source current of the sensor-gate transistor, may be the cumulative drain current of those selected transistors that are activated by the input lines (e.g., selected weighting transistors of W₁ through W_{N}) and which are supplied voltage by one or more activated select line (e.g., V_{DD} for positive weights and/or V_{DD} for negative weights). The cumulative drain current may include impedance and load balancing effects. The parallel transistors can have a shared drain voltage, V_{drain}, and a shared source voltage, V_{source} or the source voltage may be selected by alterative select lines. The drain current and drain voltage of the parallel transistors may be the source current and source voltage of the amplifying transistor—for example one or more of the parallel transistors may share a drain region or may share a conductive region which is both the drain of at least one of the parallel transistors and a source region for the amplifying transistor. Alternatively, the drains of the parallel transistors may be electrically coupled to the source of the amplifying transistor, through electrically conductive elements (e.g., metal lines, highly doped areas), including connected through various levels of a chips such as through vias, etc. The electrical connection between an output or drain of the parallel transistors and the source of the amplifying transistor may include other electrical elements, including capacitive elements, resistive elements, junctions between materials which may function Schottky junctions, etc.

The output of the parallel transistors as switched by the amplifying transistor may be read using a word line and bit line and, optionally, a select transistor. The output of the parallel transistors as switched by the amplifying transistor may be summed or differences, such as by kernel, and may include determination of a convolution of a set of selected amplifying transistor outputs. The output of multiple sensors or pixels may be read in a sensor array. The output of multiple sensors or pixels may be read as a set of overlapping or non-overlapping strides. Multiple sensors or pixels may be connected to each of the parallel input lines, or to some of a set of input lines such that multi-channel and/or multi-kernel calculations may take place at some or all of the pixels or sensors of the sensor array. The amplifying transistor and, optionally, the select transistor enable reading of the output of the sensor and a product of the weighting (or other value) applied by the parallel transistors.

In some cases, multiple transistors may comprise the memory and/or logic instead of the single transistors depicted in the some of the accompanying figures. Additionally, the parallel transistors may also comprise one or more transistor in series and/or multiple parallel transistors electrically coupled with a single input line. For example, instead of varying W/L or width, each of a set of parallel transistors may have the same W/L and each input line can be connected to a varying number of transistors such that when an input line A is activated the output current and voltage is derived from a number A of the parallel transistors and when in input line B is activated the output current and voltage is derived from a number B of the parallel transistors. Each of the input lines corresponding to different widths or varying number of transistors may represent individual kernels, such as those corresponding to a given neural network layer. Thus, multiple parallel transistors may constitute multiple kernels for a given neural network and/or a given neural network layer. Transistors with different widths or variations in the number of transistors for each kernel may constitute multi-bit weights for respective kernels of a given neural network layer.

As technology advances, data generation has increase exponentially and processing demands have correspondingly increased. For example, state-of-the-art high-resolution cameras generate vast amounts of data which require processing and which has motivated some energy-efficient on-device AI solutions. Visual data in such cameras may be captured in analog voltages by a sensor pixel array, and then converted to the digital domain for subsequent AI processing using analog-to-digital converters (ADC). Some image dependent applications may use massively parallel low-power analog/digital computing in the form of near- and in-sensor processing, in which the AI computation may performed partly in the periphery of the pixel array and partly in a separate on-board CPU/accelerator. Unfortunately, high-resolution input images may still need to be streamed between the camera and the AI processing unit, frame by frame, which may cause energy, bandwidth, and security bottlenecks. In some embodiments, to mitigate these problems, a Processing-in-Pixel-in-memory (P²M) paradigm is proposed. In one or more embodiment, the P²M paradigm may customize a pixel array by adding support for analog multi-channel, multi-bit convolution, batch normalization, and Rectified Linear Units (ReLU). In some embodiments, the P²M paradigm may include a holistic algorithm-circuit co-design approach and the resulting P²M paradigm may be used as a drop-in replacement for embedding the memory-intensive first few layers of convolutional neural network (CNN) models within foundry-manufacturable CMOS image sensor platforms. Some embodiments are validated by experimental results that indicate that P²M may reduce data transfer bandwidth from sensors and analog to digital conversions by ˜21 times, and the energy-delay product (EDP) incurred in processing a MobileNetV2 model on a TinyML use case for visual wake words dataset (VWW) by up to ˜11 times compared to standard near-processing or in-sensor implementations, without any significant drop in test accuracy.

Today's widespread applications of computer vision—spanning surveillance, disaster management, camera traps for wildlife monitoring, autonomous driving, smartphones, etc.—are fueled, at least in part, by the remarkable technological advances in image sensing platforms and the ever-improving field of deep learning algorithms. However, hardware implementations of vision sensing and vision processing platforms have traditionally been physically segregated. For example, vision sensor platforms based on CMOS technology may act as transduction entities that convert incident light intensities into digitized pixel values, such as through a two-dimensional array of photodiodes. The vision data generated from such CMOS Image Sensors (CIS) is often processed elsewhere in a cloud environment consisting of CPUs and GPUs. This physical segregation may lead to bottlenecks in throughput, bandwidth, and energy-efficiency for applications that require transferring large amounts of data from the image sensor to the back-end processor, such as object detection and tracking from high-resolution images/videos.

To address these bottlenecks, some attempts have been made to bring intelligent data processing closer to the source of the vision data, e.g., closer to the CIS, taking one of three broad approaches—(1) near-sensor processing, (2) in-sensor processing, and (3) in-pixel processing. Near-sensor processing may attempt to incorporate a dedicated machine learning accelerator chip on the same printed circuit board, or even 3D-stacked with the CIS chip. Although this may enable processing of the CIS data closer to the sensor rather than in the cloud, the approach may still suffer from the data transfer costs between the CIS and processing chip. Alternatively, in-sensor processing solutions may integrate digital or analog circuits within the periphery of the CIS sensor chip, which may reduce the data transfer between the CIS sensor and processing chips. Nevertheless, both of these approaches may still require data to be streamed (or read in parallel) through a bus from CIS photo-diode arrays into the peripheral processing circuits. In contrast, in-pixel processing solutions, may attempt to embed processing capabilities within the individual CIS pixels. Some efforts have focused on in-pixel analog convolution operation, but many such schemes may require the use of emerging non-volatile memories or 2D materials. Unfortunately, these technologies may not yet be mature and thus may not be amenable to the existing foundry-manufacturing of CIS. Moreover, these schemes may fail to support the multi-bit, multi-channel convolution operations, batch normalization (BN), and Rectified Linear Units (ReLU) needed for most practical deep learning applications. Furthermore, digital CMOS-based in-pixel hardware, which may be organized as pixel-parallel single instruction multiple data (SIMD) processor arrays, may not support convolution operations, and may thus be limited to toy workloads, such as digit recognition. Many of these schemes may rely on digital processing which typically yields lower levels of parallelism compared to their analog in-pixel alternatives. In contrast, other approaches may leverage in-pixel parallel analog computing, wherein the weights of a neural network are may be represented as the exposure time of individual pixels. This approach may require weights to be made available for manipulating pixel-exposure time through control pulses, which may lead to a data transfer bottleneck between the weight memories and the sensor array. Thus, none of the existing schemes seems to provide an in-situ CIS processing solution where both the weights and input activations are available within individual pixels that efficiently implements critical deep learning operations such as multi-bit, multi-channel convolution, BN, and ReLU operations. Furthermore, many existing in-pixel computing solutions have been developed on targeted datasets that do not represent realistic applications of machine intelligence mapped onto state-of-the-art CIS. Specifically, some prior attempted solutions are focused on simplistic datasets like MNIST, or CIFAR-10 dataset which has input images with a significantly low resolution (e.g., 32 by 32), that does not represent images captured by state-of-the-art high resolution CIS. None of which is to suggest that any technique suffering to some degree from these issues or other issues described in the previous paragraphs is disclaimed or that any other subject matter is disclaimed.

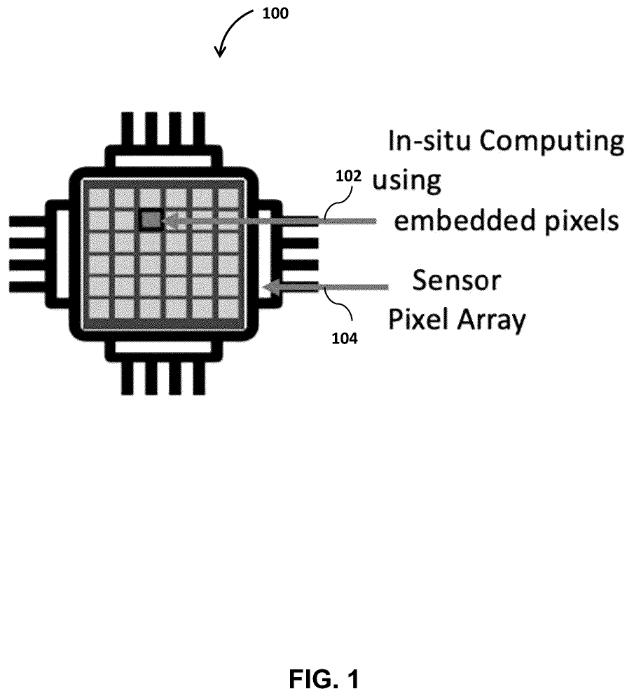

In some embodiments, an in-situ computing paradigm at the sensor nodes, herein called “Processing-in-Pixel-in-Memory (P²M)”, such as illustrated in FIG. 1, that may incorporate both the network weights and activations to enable massively parallel, high-throughput intelligent computing inside CISs is provided. In particular, the circuit architecture of one or more embodiment may not only enables in-situ multi-bit, multi-channel, dot product analog acceleration needed for convolution, but may also re-purposes the on-chip digital correlated double sampling (CDS) circuit and single slope ADC (SS-ADC) typically available in conventional CIS to implement all the required computational aspects for the first few layers of a state-of-the-art deep learning network. Furthermore, in some embodiments, the proposed architecture may be coupled with a circuit-algorithm co-design paradigm that may capture the circuit non-linearities, limitations, and bandwidth reduction goals for improved latency and energy-efficiency. In some embodiments, the resulting paradigm may demonstrate feasibility for enabling complex, intelligent image processing applications (beyond toy datasets), on high resolution images of Visual Wake Words (VWW) dataset, catering to a real-life TinyML application. For some embodiments, evaluation of efficacy was performed on TinyML applications, as they may impose tight compute and memory budgets, that are otherwise difficult to meet with current in- and near-sensor processing solutions, particularly for high-resolution input images.

FIG. 1 depicts a schematic representation of an example embodiment for processing-in-pixel-in-memory (P2M). In FIG. 1, an integrated sensor pixel array 104 and in-situ computing using the embedded pixels 102 is depicted.

In one or more embodiments, one or more of the following may apply:
The processing-in-pixel-in-memory (P²M) paradigm may be provided for resource-constrained sensor intelligence applications, wherein memory-embedded pixels enable massively parallel dot product acceleration using in-situ input activations (photodiode currents) and in-situ weights all available within individual pixels.
Re-purposing of on-chip memory-embedded pixels, CDS circuits and SS-ADCs to implement positive and negative weights, BN, and digital ReLU functionality within the CIS chip, thereby mapping all the computational aspects for the first few layers of a complex state-of-the-art deep learning network within CIS.
A dataset specific model, such as a compact MobileNet-V2 based model, may be developed optimized specifically for P²M-implemented hardware constraints, and the P²M paradigm may have its accuracy and energy-delay product (EDP) benchmarked on the VWW dataset, which represents a common use case of visual TinyML.

The ubiquitous presence of CIS-based vision sensors and their processing demands have driven the need to enable machine learning computations closer to the sensor nodes. However, given the computing complexity of modern CNNs, such as Resnet-18 and SqueezeNet, it may not be feasible to execute the entire deep-learning network, including all the layers, within the CIS chip. As a result, recent intelligent vision sensors which may be equipped with basic AI processing functionality (e.g., computing image metadata), may feature a multi-stacked configuration consisting of separate pixel and logic chips that must rely on high and relatively energy-expensive inter-chip communication bandwidth.

In some embodiments, alternatively, the P²M paradigm may show that embedding at least part of the deep learning network within pixel arrays in an in-situ manner may lead to a significant reduction in data bandwidth (and hence energy consumption) between sensor chip and downstream processing for the rest of the convolutional layers. This may be because the first few layers of carefully designed CNNs may have a significant compressing property, e.g., the output feature maps have reduced bandwidth/dimensionality compared to the input image frames. In particular, in some embodiments, the P²M paradigm may enable mapping of the computations of the first few layers of a CNN into the pixel array. In some embodiments, the P²M paradigm may include a holistic hardware-algorithm co-design framework that may capture the specific circuit behavior, including circuit non-idealities, and hardware limitations, during the design, optimization, and training of the proposed machine learning networks. The trained weights for the first few network layers may then be mapped to specific transistor sizes in the pixel-array. Because the transistor widths are fixed during manufacturing, the corresponding CNN weights may lack programmability. Fortunately, it is common to use the pre-trained versions of the first few layers of modern CNNs as high-level feature extractors are common across many vision tasks. Hence, in some embodiments, the fixed weights in the first few CNN layers may not limit the use of the P²M paradigm for a wide class of vision applications. Moreover, in some embodiments, memory-embedded pixel may also work seamlessly by replacing fixed transistors with emerging non-volatile memories, as will be discussed later. Finally, in some embodiments, the presented P²M paradigm may be used in conjunction with existing near-sensor processing approaches for added benefits, such as, improving the energy-efficiency of the remaining convolutional layers.

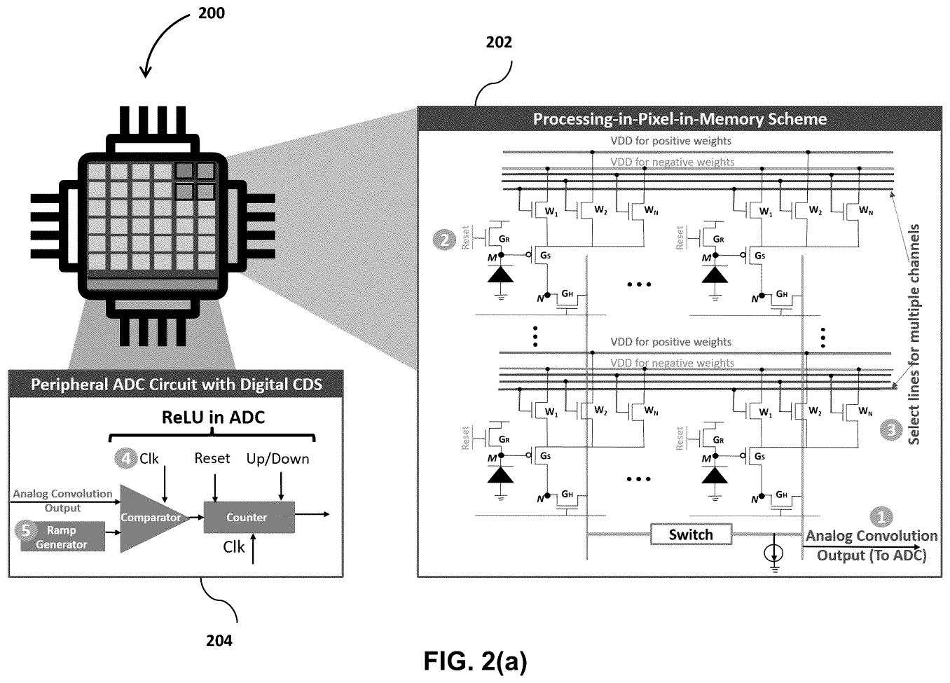

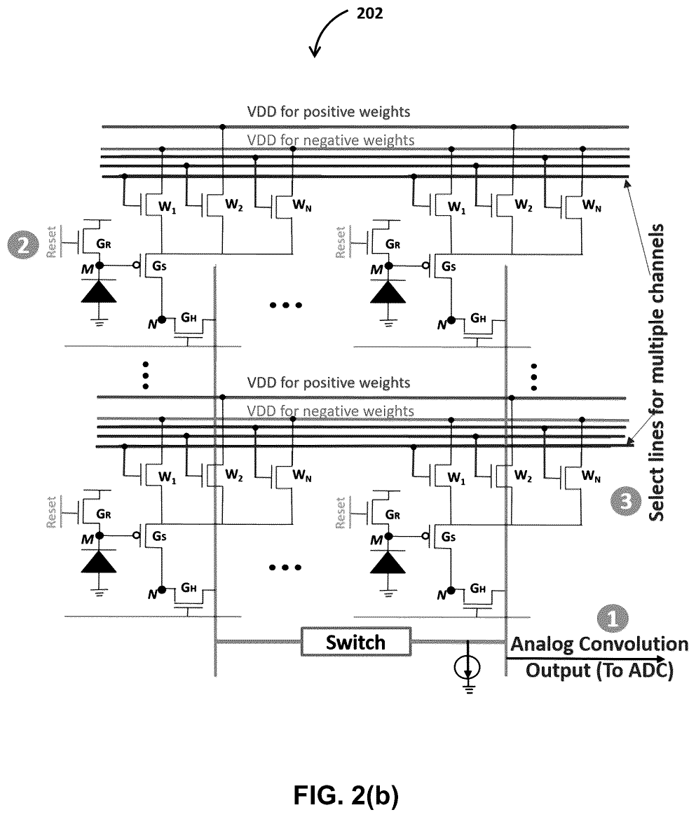

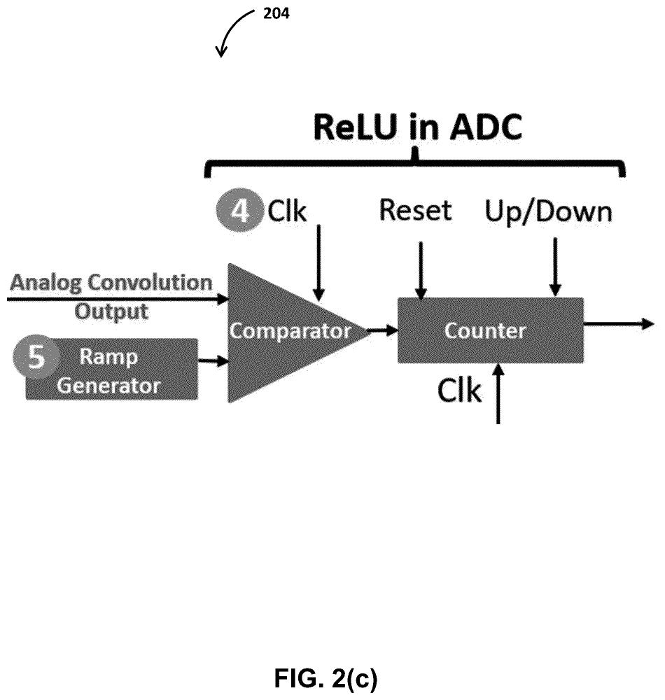

In some embodiments, all the computational aspects for the first few layers of a complex CNN architecture may be embedded within the CIS. An overview of our proposed pixel array that enables the availability of weights and activations within individual pixels with appropriate peripheral circuits is shown in FIG. 2(a)-2(c).

FIG. 2(a) depicts an example circuit techniques for mapping of computational aspects of the first few layers of a CNN layer within a CIS pixel array. FIG. 2(a) depicts a sensor array 200 with in-situ computing 200, depicted for different pixel colors. Each pixel of the sensor array 200 may contain embedded processing, such as shown in circuit diagram 202. The sensor array 200 may also contain peripheral processing, as shown in circuit diagram 204.

FIG. 2(b) depicts a schematic representation of summation over multiple pixels for a P2M scheme. FIG. 2(b) depicts circuit diagram 202, containing a V_{DD} for positive weights, a V_{DD} for negative weights, reset gate signals, select lines for multiple channels, switches, and output to analog convolution.

FIG. 2(c) depicts a schematic representation of a peripheral analog to digital converter (ADC) with digital correlated double sampling (CDS). FIG. 2(c) depicts circuit diagram 204, containing a ramp generator, comparator, and counter, where the comparator and counter function as an ReLU.

### Multi-Channel, Multi-Bit Weight Embedded Pixels

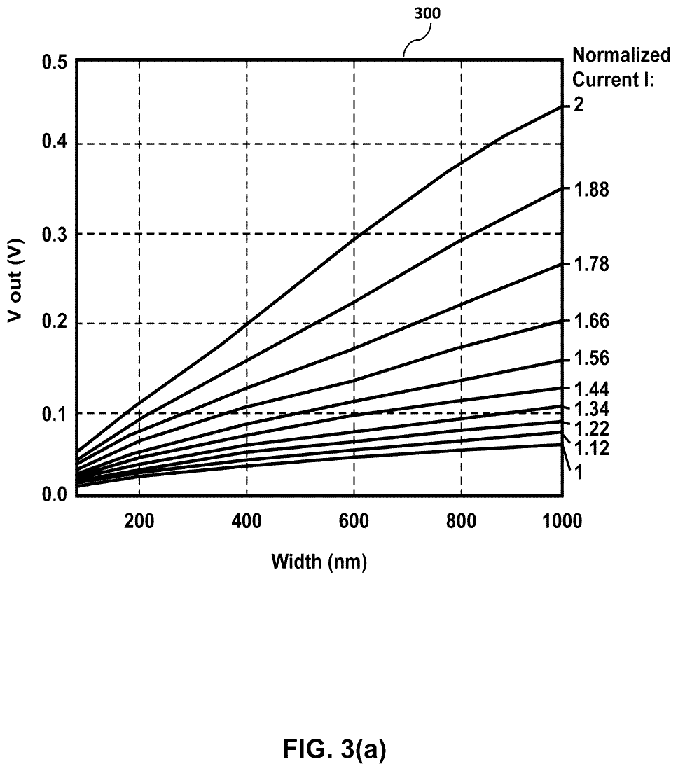

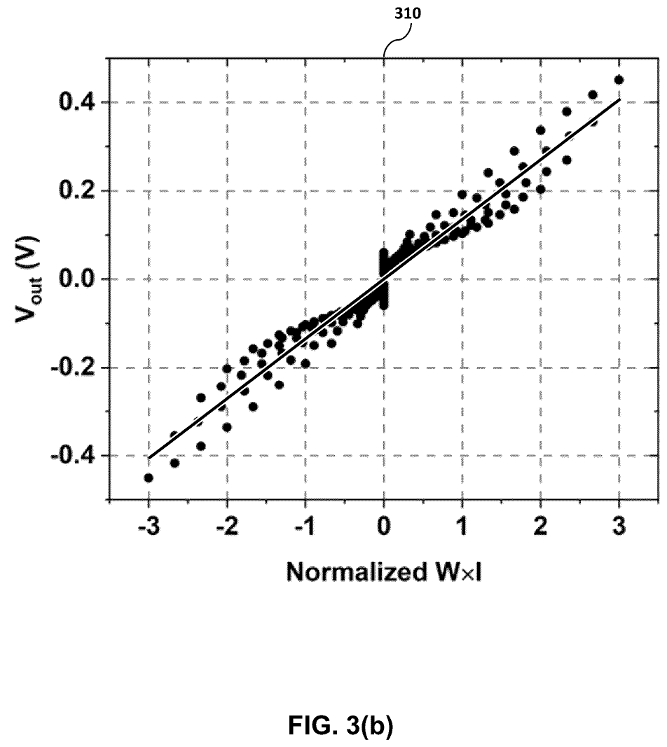

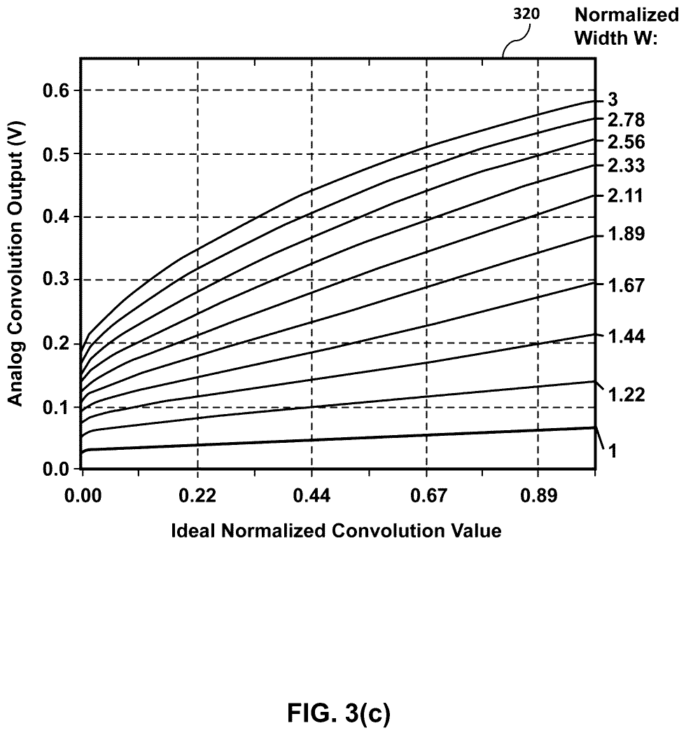

In some embodiments, the pixel circuit builds upon the standard three transistor pixel by embedding additional transistors Wᵢs that represent weights of the CNN layer, as shown in FIG. 2. Each weight transistor Wᵢ is connected in series with the source-follower transistor Gₛ. When a particular weight transistor Wᵢ is activated (by pulling its gate voltage to V_{DD})), the pixel output is modulated both by the driving strength of the transistor Wi and the voltage at the gate of the source-follower transistor Gₛ. A higher photo-diode current implies the PMOS source follower is strongly ON, resulting in an increase in the output pixel voltage. Similarly, a higher width of the weight transistor Wi results in lower transistor resistance and hence lower source degeneration for the source follower transistor, resulting in higher pixel output voltage. Graph 300 of FIG. 3(a), obtained from SPICE simulations using 22 nm node technology exhibits the desired dependence on transistor width and input photo-diode current. Thus, the pixel output performs an approximate multiplication of the input light intensity (voltage at the gate of transistor Gₛ) and the weight (or driving strength) of the transistor Wᵢ, as exhibited by the plot 310 in FIG. 3(b). The approximation may stem from the fact that transistors are inherently non-linear. As described in further detail later, a hardware-algorithm co-design framework may be leveraged to incorporate the circuit non-linearities within the CNN training framework, thereby maintaining classification accuracy. Multiple weight transistors Wᵢs may be incorporated within the same pixel and may be controlled by independent gate control signals. Each weight transistor implements a different channel in the output feature map of the layer. Thus, the gate signals represent select lines for specific channels in the output feature map. Note, it may be desirable to reduce the number of output channels so as to reduce the total number of weight transistors embedded within each pixel while ensuring high test accuracy for VWW. In some embodiments, using a holistic hardware-algorithm co-design framework described in more detail later), the number of channels in the first layer was able to be reduced from 16 to 8, which may imply that the proposed circuit may operate successfully with 8 weight transistors per pixel, which, based on current fabrication techniques, may be reasonably implemented

In some embodiments, the circuit may support both overlapping and non-overlapping strides depending on the number of weight transistors Wᵢs per pixel. Specifically, each stride for a particular kernel may be mapped to a different set of weight transistors over the pixels (e.g., representing input activations). The transistors Wᵢs may represent multi-bit weights as the driving strength of the transistors may be controlled over a wide range based on transistor width, length, and threshold voltage.

### In-Situ Multi-Pixel Convolution Operation

To achieve the convolution operation, multiple pixels may be activated. In the specific case of VWW, X×Y×3 pixels may be activated at the same time, where X and Y denote the spatial dimensions and 3 corresponds to the RGB (red, blue, green) channels in the input activation layer. For each activated pixels, the pixel output is modulated by the photo-diode current and the weight of the activated Wi transistor associated with the pixel, in accordance with FIG. 3(a),(b). In some embodiments, tor a given convolution operation only one weight transistor is activated per pixel, corresponding to a specific channel in the first layer of the CNN. The weight transistors Wi represent multi-bit weights through their driving strength. As previously described, for each pixel, the output voltage approximates the multiplication of light intensity and weight. For each bit line, shown as vertical summation across pixel lines in FIG. 2(b), the cumulative pull up strength of the activated pixels connected to that line may drive it high. The increase in pixel output voltages may accumulate on the bit lines implementing an analog summation operation. Consequently, the voltage at the output of the bit lines may represent the convolution operation between input activations and the stored weight inside the pixel.

Graph 320 of FIG. 3(c) plots the output voltage (at node Analog Convolution Output in FIG. 2(b)) as a function of normalized ideal convolution operation. The plot in the figure was generated by considering 75 pixels as activated, simultaneously. For output each line in FIG. 3c, the activated weight transistors Wᵢ are chosen to have the same width with the set of grayscale lines represents the range of widths. For each line, the input I is swept from its minimum to maximum value and the ideal dot product is normalized and plotted on x-axis. The y-axis plots the simulated SPICE circuit output. The largely linear nature of the plot indicates that the circuits are working as expected, where the small amount of non-linearities may be accounted for in a training framework described more fully later.

In order to generate multiple output feature maps, the convolution operation may have to be repeated for each channel in the output feature map. The corresponding weight for each channel may be stored in a separate weight transistor embedded inside each pixel. Thus, there may be as many weight transistors embedded within a pixel as there are number of channels in the output feature map. In some embodiments, even though it is possible to reduce the number of filters to 8 without any significant drop in accuracy for the VWW dataset, if needed or desired, it is also possible to increase the number of filters to 64 (e.g., since many SOTA CNN architectures have up to 64 channels in their first layer), without significant increase in area using advanced 3D integration, as will be discussed in more detail later.

In summary, the presented scheme (e.g., the P²M paradigm) may perform in-situ multi-bit, multi-channel analog convolution operation inside the pixel array, wherein both input activations and network weights are present within individual pixels.

### Re-Purposing Digital Correlated Double Sampling Circuit and Single-Slope ADCs as ReLU Neurons

Weights in a CNN layer may span positive and negative values. As discussed previously, weights (e.g., in the P²M paradigm) may be mapped by the driving strength (or width) of transistors Wᵢs. As the width of transistors cannot be negative, the Wᵢ transistors themselves cannot directly represent negative weights. This issue may be circumvented by re-purposing on-chip digital CDS circuit present in some commercial CIS. A digital CDS may be implemented in conjunction with column parallel Single Slope ADCs (SS-ADCs) for analog to digital conversion. A single slope ADC may consist of a ramp-generator, a comparator, and a counter (see FIG. 2(c)). An input analog voltage may be compared through the comparator to a ramping voltage with a fixed slope, generated by the ramp generator. A counter, which may be initially reset and supplied with an appropriate clock, may keep counting until the ramp voltage crosses the analog input voltage. At this point, the output of counter may be latched and may represent the converted digital value for input analog voltage. A traditional CIS digital CDS circuit may take as input two correlated samples at two different time instances, for example. The first sample may correspond to the reset noise of the pixel and the second sample to the actual signal superimposed with the reset noise. A digital CIS CDS circuit may then take the difference between the two samples, thereby, eliminating reset noise during ADC conversion. In an SS-ADC the difference may be taken by making the counter ‘up’ count for one sample and ‘down’ count for the second.

In some embodiments, this noise cancelling and differencing behavior of the CIS digital CDS circuit which may be already available on commercial CIS chips may be utilized to implement positive and negative weights and implement rectification (e.g. ReLU). In some embodiments, each weight transistor embedded inside a pixel is ‘tagged’ as either a positive or a ‘negative weight’ by connecting it to ‘top lines’ (marked as V_{DD} for positive weights in FIG. 2(b)) and ‘middle lines’ (marked as V_{DD} for negative weights in FIG. 2(b)). In some embodiments, it may be possible for a weight transistor to function as both a ‘negative weight’ and ‘positive weight’ at different times by connection to multiple different drain voltage supplies. For each channel, multiple pixels may be activated, to perform an inner-product and read out two samples. The first sample may correspond to a high V_{DD} voltage applied on the ‘top lines’ (marked as V_{DD} for positive weights in FIG. 2(b)) while the ‘middle lines’ (marked as V_{DD} for negative weights in FIG. 2) are kept at ground. The accumulated multi-bit dot product result may be digitized by the SS-ADC, while the counter is ‘up’ counting. The second sample, on the other hand, may correspond to a high V_{DD} voltage applied on the ‘middle lines’ (marked as VDD for negative weights in FIG. 2(b)) while the ‘top lines’ (marked as V_{DD} for positive weights in FIG. 2(b)) are kept at ground. The accumulated multi-bit dot product result may again be digitized and also be subtracted from the first sample by the SS-ADC, while the counter is ‘down’ counting. Thus, the digital CDS circuit may first accumulate the convolution output for all positive weights and then subtracts the convolution output for all negative weights for each channel, controlled by respective select lines for individual channels. In some embodiments, possible sneak (e.g., leakage) currents flowing between weight transistors representing positive and negative weights may be obviated by integrating a diode in series with weight transistors or by simply splitting each weight transistor into two series connected transistors, where the channel select lines may control one of the series connected transistor, while the other transistor is controlled by a select line representing positive/negative weights.

In some embodiments, re-purposing the on-chip CDS for implementing positive and negative weights may also allow for implement of a quantized ReLU operation inside the SS-ADC. ReLU operations may clip negative values to zero. In some embodiments, this may be achieved by ensuring that the final count value latched from the counter (after the CDS operation consisting of ‘up’ counting and then ‘down’ counting’) is either positive or zero. In some embodiments, before performing the dot product operation, the counter may be reset to a non-zero value representing the scale factor of the BN layer (as will be described in further detail later). Thus, by embedding multi-pixel convolution operation and re-purposing on-chip CDS and SS-ADC circuit for implementing positive/negative weights, batch-normalization and ReLU operation, in some embodiments the P²M scheme may implement substantially all the computational aspect for the first few layers of a complex CNN within the pixel array enabling massively parallel in-situ computations.

In embodiments with these features operating together, the proposed P²M circuit may compute one channel at a time and have three phases of operation as follows:
Reset Phase: First, the voltage on the photodiode node M (see FIG. 2(b)) may be pre-charged or reset by activating the reset transistor Gᵣ. In some embodiments, in order to perform multi-pixel convolution, the set of pixels X×Y×3 may be reset simultaneously.
Multi-pixel Convolution Phase: In some embodiments, next the gate of the reset transistor Gᵣ may be discharged, which deactivates Gᵣ. Subsequently, the X×Y×3 pixels may be activated by pulling the gate of respective G_{H} transistors to V_{DD}. Within the activated set of pixels, a single weight transistor corresponding to a particular channel in the output feature map may be activated, by pulling high its gate voltage through the select lines (labeled as select lines for multiple channels in FIG. 2(b)). As the photodiode is sensitive to the incident light, photo-current is generated as light shines upon the diode (for a duration equal to exposure time), and voltage on the gate of Gₛ may be modulated in accordance with the photodiode current that is proportional to the intensity of incident light. The pixel output voltage may therefor be a function of the incident light (voltage on node M of FIG. 2) and the driving strength of the activated weight transistor within each pixel. Pixel output from multiple pixels may be accumulated on the column-lines and may represent the multi-pixel analog convolution output. The SS-ADC in the periphery may convert analog output to a digital value. In some embodiments, the entire operation may be repeated twice, one for positive weights (‘up’ counting) and another for negative weights (‘down counting’).
ReLU Operation: In some embodiments, after the above operations, the output of the counter may be latched and represent a quantized ReLU output. Rectification may ensure that the latched output is either positive or zero, thereby mimicking the ReLU functionality within the SS-ADC.

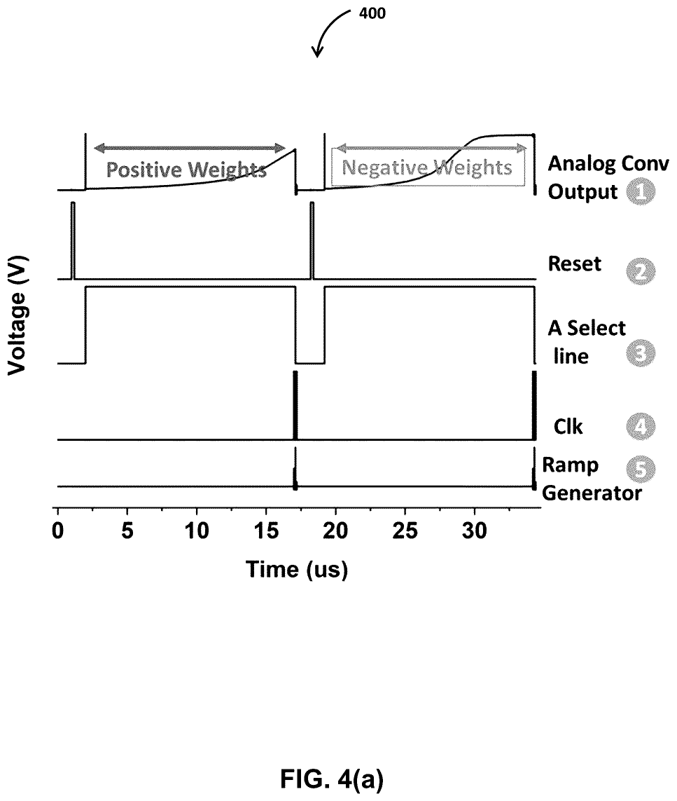

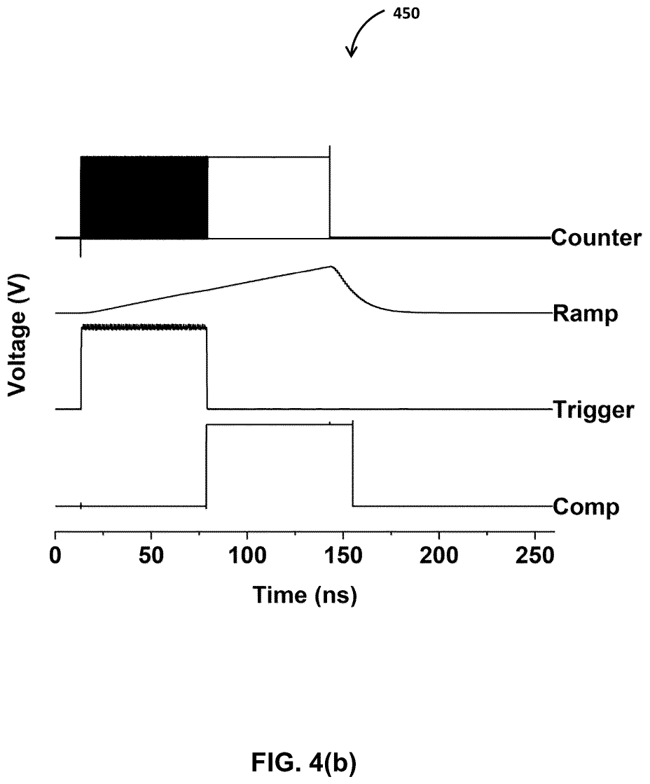

The entire P²M circuit of one or more embodiment may be simulated using commercial 22 nm node FD-SOI (fully depleted silicon-insulator) technology. In some embodiments, the SS-ADCs may be implemented using a using a bootstrap ramp generator and dynamic comparators. In some embodiments, it may be assumed that the counter output which represents the ReLU function is an N-bit integer, it may need 2N cycles for a single conversion. The ADC may be supplied with a 2 GHz clock for the counter circuit. SPICE simulations exhibiting the multiplicative nature of weight transistor embedded pixels with respect to photodiode current is shown in FIG. 3(a),(b). Functional behavior of the circuit for analog convolution operation is depicted in FIG. 3(c). A typical timing waveform showing pixel operation along with SS-ADC operation simulated on 22 nm technology node is shown in graph 450 of FIG. 4(b).

In some embodiments, various circuit functions already available in commercial cameras may be re-purposed for the P²M paradigm. This may ensure that most of the existing peripheral and corresponding timing control blocks require only minor modification to support the P²M computations. Specifically, in some embodiments, instead of activating one row at a time in a rolling shutter manner, P²M may require activation of group of rows, simultaneously, corresponding to the size of kernels in the first layers. Multiple group of rows may then be activated in a typical rolling shutter format. Overall, in some embodiments, the sequencing of pixel activation (except for the fact that group of rows have to be activated instead of a single row), CDS, ADC operation and bus-readout may be similar to typical cameras.

### CIS Process Integration and Area Considerations

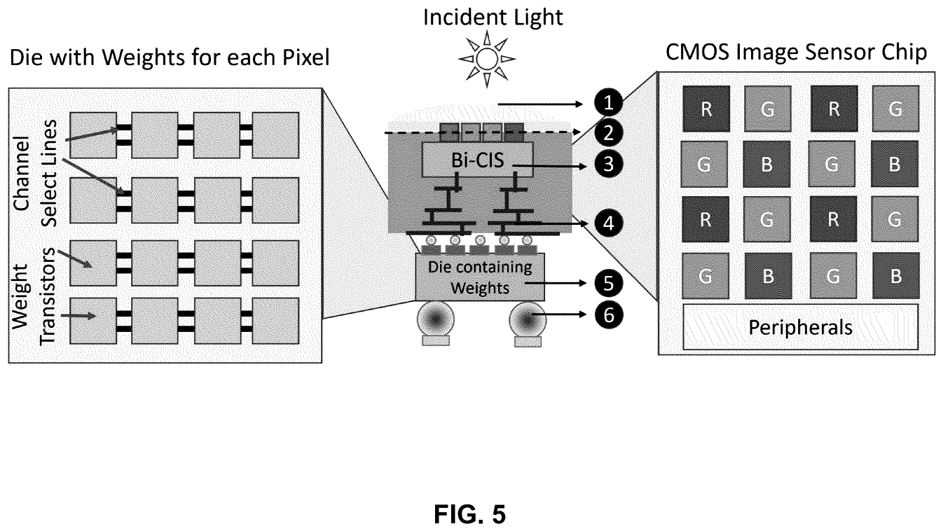

In some embodiments, the proposed P²M paradigm featuring memory-embedded pixels may be particularly viable with respect to its manufacturability using existing foundry processes. A representative illustration of a heterogeneously integrated system catering to the needs of the proposed P²M paradigm is shown in FIG. 5. The figure consists of two key elements, (i) backside illuminated CMOS image sensor (Bi-CIS), consisting of photo-diodes, read-out circuits and pixel transistors (reset, source follower and select transistors), and (ii) a die consisting of multiple weight transistors per pixel (refer FIG. 2(b)). From FIG. 2(b), it may be seen that each pixel may consist of multiple weight transistors that may lead to exceptionally high area overhead. However, with the presented heterogeneous integration scheme of FIG. 5, the weight transistors may be vertically aligned below a standard pixel, thereby incurring no (or minimal) increase in footprint. Specifically, each Bi-CIS chip may be implemented in a leading or lagging technology node. The die consisting of weight transistors may be built on an advanced planar or non-planar technology node such that the multiple weight transistors may be accommodated in the same footprint occupied by a single pixel (which assumes that pixel sizes may be larger than the weight transistor embedded memory circuit configuration). The Bi-CIS image sensor chip/die may be heterogeneously integrated through a bonding process (die-to-die or die-to-wafer) integrating it onto the die consisting of weight transistors. In some embodiments, a die-to-wafer low-temperature metal-to-metal fusion with a dielectric-to-dielectric direct bonding hybrid process may preferentially achieve high-throughput sub-micron pitch scaling with precise vertical alignment. One of the advantages of adapting heterogeneous integration technology may be that chips of different sizes may be fabricated at distinct foundry sources, technology nodes, and functions and then integrated together. In embodiments where there are any limitations due to the increased number of transistors in the die consisting of the weights, a conventional pixel-level integration scheme, such as Stacked Pixel Level Connections (SPLC), which shields the logic CMOS layer from the incident light through the Bi-CIS chip region, may also provide a high pixel density and a large dynamic range. Alternatively, in some embodiments, through silicon via (TSV) integration technique may also be adopted for front-side illuminated CMOS image sensor (Fi-CIS), wherein the CMOS image sensor may be bonded onto the die consisting of memory elements through a TSV process. In some embodiments, in the Bi-CIS, the wiring may be moved away from the illuminated light path allowing more light to reach the sensor, which may give better low-light performance.

In some embodiments, the heterogeneous integration scheme may be used (e.g., advantageously) to manufacture P²M sensor systems on existing as well as emerging technologies. In some embodiments, the die consisting of weight transistors may use a ROM-based structure as previously discussed or other emerging programmable non-volatile memory technologies like PCM, RRAM, MRAM, ferroelectric field effect transistors (FeFETs), etc., which may be manufactured in distinct foundries and subsequently heterogeneously integrated with the CIS die. Thus, the proposed heterogeneous integration may allow achievement of lower area-overhead, while simultaneously enabling seamless, massively parallel convolution. Specifically, for some embodiments, based on reported contacted poly pitch and metal pitch numbers, it is estimated that more than 100 weight transistors may be embedded in a 3D integrated die using a 22 nm technology, assuming the underlying pixel area (dominated by the photodiode) is 10 μm ×10 μm. In some embodiments, availability of back-end-of-line monolithically integrated two terminal non-volatile memory devices may allow denser integration of weights within each pixel. Such weight embedded pixels may individual pixels to have in-situ access to both activation and weights as needed by the P²M paradigm which may obviate the need to transfer weights or activation from one physical location to another through a bandwidth constrained bus. Hence, unlike other multi-chip solutions, in some embodiments the P²M paradigm may not incur or may reduce energy bottlenecks.

### P²M-Constrained Algorithm-Circuit Co-Design

In some embodiments, algorithmic optimizations to standard CNN backbones may be used that are guided by one or more of the following: (1) P²M circuit constraints which may arise due to analog computing nature of the proposed pixel array and the limited conversion precision of on-chip SS-ADCs, (2) the need for achieving state-of-the-art test accuracy, and (3) maximizing desired hardware metrics of high bandwidth reduction, energy-efficiency and low-latency of P²M computing, and meeting the memory and compute budget of the VWW application.

### Custom Convolution for the First Layer Modeling Circuit Non-Idealities

From an algorithmic perspective, the first layer of a CNN may be a linear convolution operation followed by BN and non-linear (ReLU) activation. In some embodiments, the P²M circuit scheme may implement a convolution operation in an analog domain using modified memory-embedded pixels. The constituent entities of these pixels may be transistors, which may be inherently non-linear devices. As such, in general, analog convolution circuits consisting of transistor devices may exhibit non-ideal non-linear behavior with respect to the convolution operation. Some previous technologies, specifically in the domain of memristive analog dot product operation, may ignore non-idealities arising from non-linear transistor devices. In contrast, in some embodiments, to determine these non-linearities, extensive simulations of the presented P²M circuit may be performed spanning wide range of circuit parameters such as the width of weight transistors and the photodiode current based on commercial 22 nm node transistor technology node. The resulting SPICE results, e.g., the pixel output voltages corresponding to a range of weights and photodiode currents, may be modeled using a behavioral curve-fitting function. In some embodiments, the generated function may then be included in an algorithmic framework, thereby replacing the convolution operation in the first layer of the network. In particular, in some embodiments, the output of the curve-fitting function may be accumulated, such as one for each pixel in the receptive field (e.g., for 3 input channels, and a kernel size of 5×5, the receptive field size may be 75), to model each inner product generated by the in-pixel convolutional layer. In some embodiments, this algorithmic framework was then used to optimize the CNN training for the VWW dataset.

### Circuit-Algorithm Co-Optimization of CNN Backbone Subject to P²M Constraints

As described previously, the P²M circuit scheme may maximize parallelism and data bandwidth reduction by activating multiple pixels and reading multiple parallel analog convolution operations for a given channel in the output feature map. The analog convolution operation may be repeated for each channel in the output feature map serially. Thus, parallel convolution in the circuit may tend to improve parallelism, bandwidth reduction, energy-efficiency and speed. However, in some embodiments, increasing the number of channels in the first layer may increase the serial aspect of the convolution and may degrade parallelism, bandwidth reduction, energy-efficiency, and speed. This may create an intricate circuit-algorithm trade-off, wherein the backbone CNN may be optimized, in some embodiments, for having larger kernel sizes (that increases the concurrent activation of more pixels, helping parallelism) and non-overlapping strides (to reduce the dimensionality in the downstream CNN layers, thereby reducing the number of multiply-and-adds and peak memory usage), smaller number of channels (to reduce serial operation for each channel), while maintaining close to state-of-the-art classification accuracy and taking into account the non-idealities associated with analog convolution operation. Also, in some embodiments, decreasing a number of channels may decrease the number of weight transistors embedded within each pixel (where each pixel may have weight transistors equal to the number of channels in the output feature map), which may improve area and power consumption. Furthermore, in some embodiments, a resulting smaller output activation map (due to reduced number of channels, and larger kernel sizes with non-overlapping strides) may reduce the energy incurred in transmission of data from the CIS to the downstream CNN processing unit and the number of floating point operations (and consequently, energy consumption) in downstream layers.

In addition, in some embodiments, the BN layer may be fused, including partly in the preceding convolutional layer, and partly in the succeeding ReLU layer to enable its implementation via P²M. For example, a BN layer with γ and β as the trainable parameters, which remain fixed during inference, may be considered. During the training phase, the BN layer may normalize feature maps with a running mean u and a running variance σ, which may be saved and used for inference. As a result, the BN layer may implement a linear function, as shown below in Equation 1.

$$Y = γ \frac{X - μ}{\sqrt{{σ}^{2} + ϵ}} + β = ( \frac{γ}{\sqrt{{σ}^{2} + ϵ}} ) \cdot X + ( β - \frac{γ μ}{\sqrt{{σ}^{2} + ϵ}} ) = A \cdot X + B \qquad ( 1 )$$

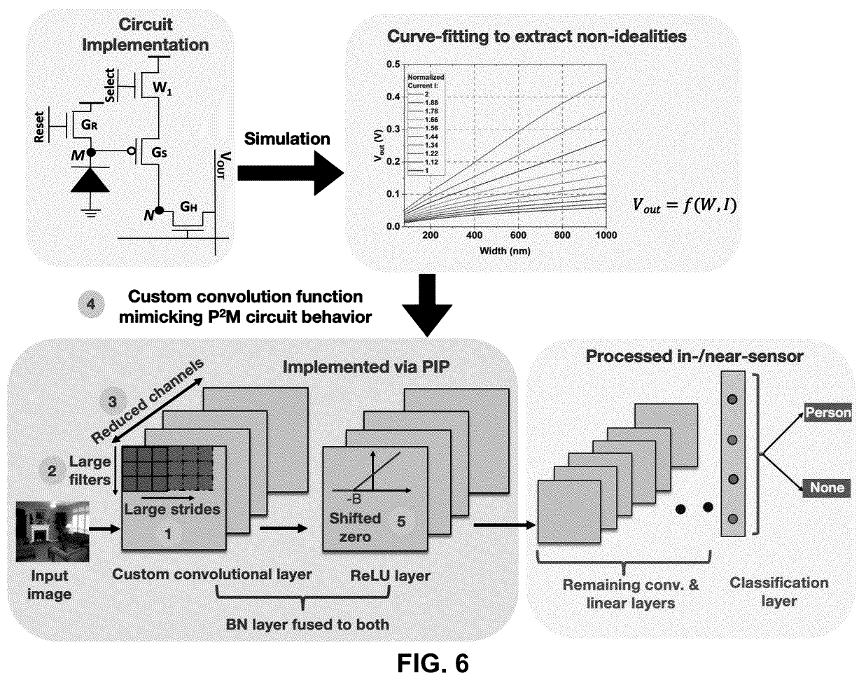

In some embodiments, the scale term A may be fused into the weights (e.g., value of the pixel embedded weight tenso is A·Θ, where Θ is the final weight tensor obtained by our training) that are embedded as the transistor widths in the pixel array. Alternatively or additionally, in some embodiments, a shifted ReLU activation function may be used, following the convolutional layer, as shown in FIG. 6 to incorporate the shift term B. In some embodiments, the counter-based ADC implementation as previously discussed may be used to implement the shifted ReLU activation. In some embodiments, this may be achieved by resetting the counter to a non-zero value corresponding to the term B at the start of the convolution operation, as opposed to resetting the counter to zero.

In some embodiments, to minimize the energy cost of the analog-to-digital conversion in our P²M approach, the layer output may be quantized to as few bits as possible subject to achieving the desired accuracy. In some embodiments, a floating-point model may be trained, including with close to state-of-the-accuracy, and then quantized in the first convolutional layer to obtain low-precision weights and activations during inference. In some embodiments, the mean, variance, and the trainable parameters of the BN layer may also be quantized, as all these affect the shift term B (e.g., of Equation 1), for the low-precision shifted ADC implementation. In some embodiments, quantization-aware training (QAT) may be avoided because it may significantly increase the training cost with no reduction in bit-precision for our model at iso-accuracy. In some embodiments, that the lack of bit-precision improvement from QAT may be the result of a small improvement in quantization of only the first layer that may have little impact on the test accuracy of the whole network.

With the bandwidth reduction obtained by any of the above described embodiments, the output feature map of the P²M-implemented layers may more easily be implemented in micro-controllers with extremely low memory footprint, where P²M itself may greatly improve the energy-efficiency of the first layer. In some embodiments, this approach may therefore enable TinyML applications that usually have a tight compute and memory budget, as which will be discussed in more detail later.

### Quantification of Bandwidth Reduction

In some embodiments, the bandwidth reduction (BR) may be estimated. For example, to quantify the bandwidth reduction after the first layer obtained by P²M (BN and ReLU layers may not yield any BR), one may let the number of elements in the RGB input image be I and in the output activation map after the ReLU activation layer be O. Then, BR can be estimated as shown in Equation 2:

$$B R = ( \frac{O}{I} ) ( \frac{4}{3} ) ( \frac{12}{{N}_{b}} ) \qquad ( 2 )$$

Here, the factor ( 4/3) may represent the compression from Bayer's pattern of RGGB pixels to RGB pixels because the additional green pixel may be ignored or design to effectively take the average of the photo-diode currents from the two green pixels. The factor

$$\frac{12}{{N}_{b}}$$

may represent the ratio or the bit-precision between the image pixels captured by the sensor (pixels may typically have a bit-depth of 12) and the quantized output of our convolutional layer denoted as N_{b}. Let us now substitute Equation 3, below:

$$O = {( \frac{i - k + 2 * p}{s} + 1 )}^{2} * {c}_{0} , \qquad ( 3 )$$

$$l = {i}^{2} * 3$$

into Equation 2, where i denotes the spatial dimension of the input image, k, p, s denote the kernel size, padding and stride of the in-pixel convolutional layer, respectively, and c₀ denotes the number of output channels of the in-pixel convolutional layer. These hyperparameters, along with N_{b} may be obtained via a thorough algorithmic design space exploration with the goal of achieving the best accuracy, subject to meeting the hardware constraints and the memory and compute budget of the TinyML benchmark. Values of hyperparameters for one or more embodiments are shown in Table 1, and by substitute them into Equation 2, a value of BR of 21× may be obtained.

TABLE 1
Model hyperparameters and their values to enable bandwidth reduction
in the in-pixel layer, in one or more embodiments.

| Hyperparameter | Value |
|---|---|
| Kernel size of the convolutional layer (k) | 5 |
| Padding of the convolutional layer (p) | 0 |
| Stride of the convolutional layer (s) | 5 |
| Number of output channels of the convolutional layer (c₀) | 8 |
| Bit-precision of the P²M-enabled convolutional layer output (N_{b}) | 8 |

### EXPERIMENTAL RESULTS

### Benchmarking Dataset and Model

In some embodiments, the P²M paradigm may be useful for TinyML applications, e.g., with models that may be deployed on low-power IoT devices with only a few kilobytes of on-chip memory. In particular, the Visual Wake Words (VWW) dataset may present a relevant use case for visual TinyML. It consists of high-resolution images that include visual cues to “wake-up” AI-powered home assistant devices, such as Amazon's Astro, that may require real-time inference in resource-constrained settings. The goal of the VWW challenge may be to detect the presence of a human in the frame with very little resources—e.g., close to 250 KB peak RAM usage and model size. To meet these constraints, current solutions may involve down-sampling the input image to medium resolution (224×224) which may cost some accuracy.

In some embodiments, the images from the COCO2014 dataset and the train-val split specified in the paper by A. Chowdery et al that introduced the VWW dataset may be used. This split may ensure that the training and validation labels are roughly balanced between the two classes ‘person’ and ‘background’; 47% of the images in the training dataset of 115 k images have the ‘person’ label, and similarly, 47% of the images in the validation dataset are labelled to the ‘person’ category. In some embodiments, the distribution of the area of the bounding boxes of the ‘person’ label remain similar across the train and val set. Hence, the VWW dataset with such a train-val split may act as a benchmark of tinyML models running on low-power microcontrollers. In some embodiments, MobileNetV2 may be chosen as a baseline CNN architecture with 32 and 320 channels for the first and last convolutional layers respectively that supports full resolution (560×560) images. In order to avoid overfitting to only two classes in the VWW dataset, in some embodiments, the number of channels in the last depthwise separable convolutional block may be decreased by 3×. Mobile-NetV2, similar to other MobileNet class of models, may be very compact with size less than the maximum allowed in the VWW challenge. It may perform well on complex datasets like ImageNet and, as described herein, does very well on VWWs.

To evaluate the P²M paradigm on MobileNetV2, in some embodiments, a custom model may be created that replaces the first convolutional layer with a P²M custom layer that captures the systematic non-idealities of the analog circuits, the reduced number of output channels, and limitation of non-overlapping strides, as discussed previously.

In some embodiments, both the baseline and P²M custom models may be trained in PyTorch using the SGD optimizer with momentum equal to 0.9 for 100 epochs. In some embodiments, he baseline model has an initial learning rate (LR) of 0.03, while the custom counterpart has an initial LR of 0.003. In some embodiments, both the learning rates decay by a factor of 0.2 at every 35 and 45 epochs. In some embodiments, after training a floating-point model with the best validation accuracy, quantization may be performed to obtain 8-bit integer weights, activations, and the parameters (including the mean and variance) of the BN layer. In some embodiments, experiments may be performed on a Nvidia 2080Ti GPU with 11 GB memory.

### Classification Accuracy

Comparison between baseline and P²M custom models: In some embodiments, the performance of the baseline and P²M custom MobileNet-V2 models on the VWW dataset may be evaluated, as shown in Table 2 below. Note that, in some embodiments, both these models are trained from scratch. In some embodiments, the baseline model may yield the best test accuracy on the VWW dataset among the models available in literature that do not leverage any additional pre-training or augmentation. Note, that in some embodiments, the baseline model may require a significant amount of peak memory and MAdds (˜30× more than that allowed in the VWW challenge), however, the baseline model may still serve a good benchmark for comparing accuracy. In some embodiments, the P²M-enabled custom model may reduce the number of MAdds by ˜7.15×, and peak memory usage by ˜25.1× with 1.47% drop in the test accuracy compared to the uncompressed baseline model for an image resolution of 560×560. In some embodiments, with the memory reduction, the P²M model may be able to run on tiny micro-controllers with only 270 KB of on-chip SRAM. In some embodiments, peak memory usage may be calculated using the same convention as A. Chowdery et al . In some embodiments, both the baseline and custom model accuracies may drop (albeit the drop may be significantly higher for the custom model) as image resolution is reduced, which may highlight the need for high-resolution images and the efficacy of P²M in both alleviating the bandwidth bottleneck between sensing and processing, and reducing the number of MAdds for the downstream CNN processing.

TABLE 2
Test accuracies, number of MAdds, and peak memory usage
of baseline and P2M custom compressed model while classifying
on the VWW dataset for different input image resolutions,
according to one or more embodiments.

| Image | | Test accuracy | Number of | Peak memory |
|---|---|---|---|---|
| Resolution | Model | (%) | MAdds (G) | usage (MB) |
| 560 × 560 | Baseline | 91.37 | 1.93 | 7.53 |
| | P²M custom | 89.90 | 0.27 | 0.30 |
| 225 × 225 | Baseline | 90.56 | 0.31 | 1.2 |
| | P²M custom | 84.30 | 0.05 | 0.049 |
| 115 × 115 | Baseline | 91.10 | 0.09 | 0.311 |
| | P²M custom | 80.00 | 0.01 | 0.013 |

Comparison with other models: Table 3, below, provides a comparison of the performances of models generated through the algorithm-circuit co-simulation framework of one or more embodiments with other TinyML models for VWW. In some embodiments, the P²M custom models yield test accuracies within 0.37% of the best performing model provided in Table 3. In some embodiments, the models may have been trained solely based on the training data provided, whereas ProxylessNAS, that won the 2019 VWW challenge leveraged additional pretraining with ImageNet. Hence, for consistency, in Table 3 the test accuracy of ProxylessNAS is reported with identical training configurations on the final network. Note that Zhoue et al. leveraged massively parallel energy-efficient analog in-memory computing to implement MobileNet-V2 for VWW, but incur an accuracy drop of 5.67% and 4.43% compared to the baseline and the ProxylessNAS models. This may imply the need for intricate algorithm-hardware co-design and accurately modeling of the hardware non-idealities in the algorithmic framework, as shown in some embodiments.

TABLE 3
Performance comparison of the proposed P²M-compatible
models with other deep CNN on VWW dataset.

| | | | Test |
|---|---|---|---|
| | | Model | accura- |
| Authors | Description | architecture | cy (%) |
| Saha et al | RNNPooling | MobileNet-V2 | 89.65 |
| Han et al | ProxylessNAS | Non-standard | 90.27 |
| | | architecture | |
| Banbury et al | Differentiable NAS | MobileNet-V2 | 88.75 |
| Zhoue et al | Analog compute-in-memory | MobileNet-V2 | 85.7 |
| P²M paradigm | P²M | MobileNet-V2 | 89.90 |

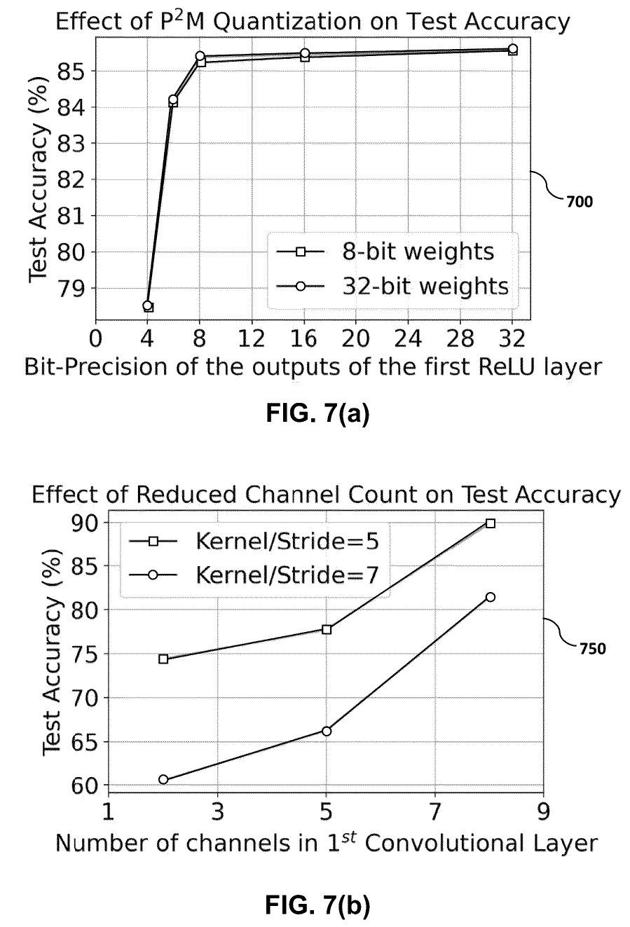

Effect of quantization of the in-pixel layer: As discussed previously, in some embodiments, the output of the first convolutional layer of the P²M model may be quantized after training, for instance to reduce the power consumption due to the sensor ADCs and compress the output as outlined in Equation 2. In some embodiments, different output bit-precisions of {4,6,8,16,32} were used to explore the trade-off between accuracy and compression/efficiency as shown in FIG. 7(a). In some embodiments, for implementation a bit-width of 8 may be chosen as it is the lowest precision that does not yield significant accuracy drop compared to the full-precision models. As shown in FIGS. 7(a) and 7(b), in some embodiments, the weights in the in-pixel layer may also be quantized to 8 bits with an 8-bit output activation map, with less than 0.1% drop in accuracy.

Ablation study: In some embodiments, an accuracy drop incurred due to each of the three modifications (e.g., nonoverlapping strides, reduced channels, and custom function) in the P²M-enabled custom model was studied. Incorporation of the non-overlapping strides (e.g., stride of 5 for 5×5 kernels from a stride of 2 for 3×3 in the baseline model) may lead to an accuracy drop of 0.58%. Reducing the number of output channels of the in-pixel convolution by 4× (e.g., 8 channels from 32 channels in the baseline model), on the top of non-overlapping striding, may reduce the test accuracy by 0.33%. Additionally, replacing the element-wise multiplication with the custom P²M function in the convolution operation may reduce the test accuracy by a total of 0.56% compared to the baseline model. In some embodiments, the in-pixel output may be further compressed by either increasing the stride value (e.g., changing the kernel size proportionately for non-overlapping strides) or decreasing the number of channels. However, both of these approaches may reduce the VWW test accuracy significantly, as shown in FIG. 7(b).

Comparison with prior works: Table 4, below, compares different in-sensor and near-sensor computing works in the literature with the proposed P²M approach in one or more embodiments. Most of these comparisons are qualitative in nature, because almost all these works have used toy datasets like MNIST, or low-resolution datasets like CIFAR-10. A fair evaluation of in-pixel computing would be done on high-resolution images captured by modern camera sensors. In some embodiments, in-pixel computing on a high-resolution dataset, such as VWW, with associated hardware-algorithm co-design is provided in the P²M paradigm, but not prior works. Moreover, in some embodiments, the P²M paradigm may implement more complex compute operations including analog convolution, batch-norm, and ReLU inside the pixel array. Additionally, the prior works, such as shown in Table 4, may use older technology node (such as 180 nm). Thus, due to major discrepancy in the use of technology nodes, unrealistic datasets for in-pixel computing, and only a sub-set of computations being implemented in prior-works, in some embodiments it is infeasible to do a fair quantitative comparison between the P²M paradigm and previous works in the literature. Nevertheless, Table 4 enumerates the key differences and compares the highlights of each work, which may provide a comparative understanding of in-pixel compute ability of the P2M paradigm work compared to previous works.

TABLE 4
Comparison of P²M of some embodiments with related
in-sensor and near-sensor computing works.

| | Tech | | High | | Supported | Acc. |
|---|---|---|---|---|---|---|
| Work | node | Computation | Resolution | Dataset | Operations | (%) |
| P²M | 22 nm | Analog | Yes | VWW | Conv, BN, | 89.90 |
| | | | | | ReLU | |
| TCAS-I 2020 | 180 nm | Analog | No | — | Binary Con. | — |
| TCSVT 2022 | 180 nm | Analog | No | CIFAR-10 | Conv. | 89.6 |
| Nature 2020 | — | Analog | No | 3-class | MLP | 100 |
| | | | | alphabet | | |
| ECCV 2020 | 180 nm | Digital | No | MNIST | MLP | 93.0 |

### EDP Estimation

In some embodiments, a circuit-algorithm co-simulation framework is developed to characterize the energy and delay of the baseline and P²M-implemented VWW models. The total energy consumption for both these models may be partitioned into three major components: sensor (Eₛₑₙₛ), sensor-to-SoC communication (E_{com}), and SoC energy (E_{soc}). Sensor energy may be further decomposed to pixel read-out (Eₚᵢₓ) and analog-to-digital conversion (ADC) cost (E_{adc}). E_{soc}, on the other hand, is primarily composed of the MAdd operations (E_{mac}) and parameter read (E_{read}) cost. Hence, the total energy may be approximated as Equation 4, below:

$${E}_{tot} \approx ( {e}_{pix} + {e}_{adc} ) * {N}_{pix} + {e}_{com} * {N}_{pix} + {e}_{mac} * {N}_{mac} + {e}_{read} * {N}_{read} \qquad ( 4 )$$

$${E}_{tot} \approx {E}_{sens} + {E}_{com} + {E}_{mac} + {E}_{read}$$

Here, eₚᵢₓ and e_{com} may represent per-pixel sensing and communication energy, respectively. e_{mac} may be the energy incurred in one MAC operation, e_{read} may represent a parameter's read energy, and Nₚᵢₓ may denote the number of pixels communicated from sensor to SoC. For a convolutional layer that takes an input I∈R^{h}^{ᵢ}^{×w}^{ᵢ}^{×c}^{ᵢ} and weight tensor 0∈R^{k×k×c}^{ᵢ}^{×c}^{₀} to produce output O∈R^{h}^{ᵢ}^{×w}^{ᵢ}^{×c}^{ᵢ}, the N_{mac} and N_{read} can be computed using Equations 5 and 6, below, as

$${N}_{mac} = {h}_{0} * {w}_{0} * {k}^{2} * {c}_{i} * {c}_{0} \qquad ( 5 )$$

$${N}_{read} = {k}^{2} * {c}_{i} * {c}_{0} \qquad ( 6 )$$

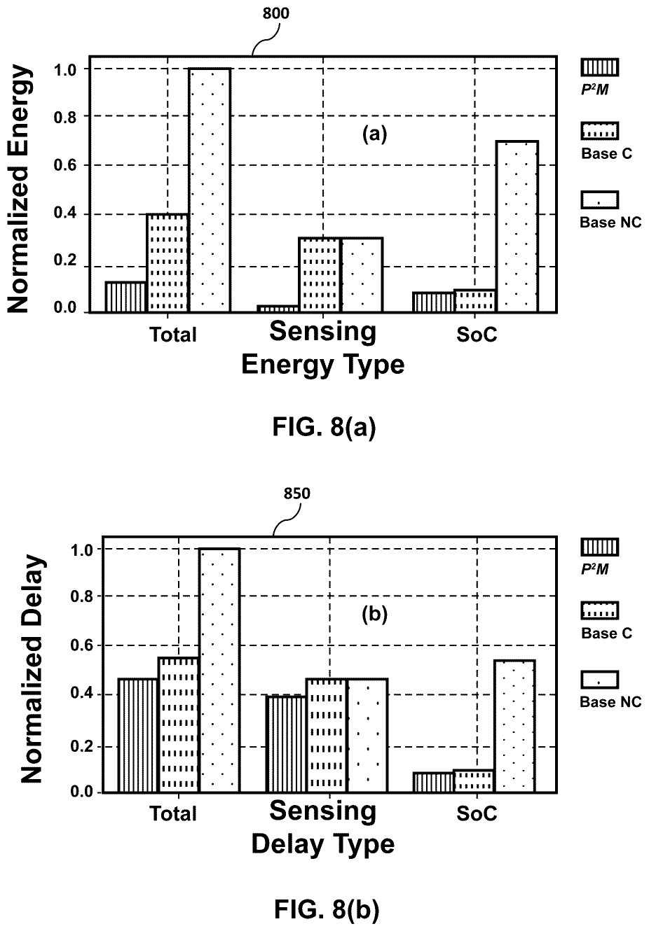

The energy values used to evaluate Eₜₒₜ are presented in Table 5, below. While eₚᵢₓ and e_{adc} may be obtained from our circuit simulations, e_{com} is obtained from Kodukula, V. et al. In some embodiments, the value of E_{read} may be ignored as it corresponds to only a small fraction (<10⁻⁴) of the total energy. Graph 800 of FIG. 8(a) shows the comparison of energy costs for standard vs P²M-implemented models. In particular, P²M, in some embodiments, may yield an energy reduction of up to 7.81×. Moreover, the energy savings may be larger when the feature map needs to be transferred from an edge device to the cloud for further processing, due to the high communication costs. Note, two baseline scenarios have been used—one with compression and one without compression. The first (compressed) baseline is MobileNetV2 which may aggressively down-sample the input similar to P²M (hᵢ/wᵢ: 560→h₀/w₀: 112). For the second (uncompressed) baseline model, standard first layer convolution kernels causing standard feature down-sampling may be assumed (hᵢ/wᵢ: 560→h₀/w₀: 279).

TABLE 5
Energy estimates for different hardware components,
according to some embodiments.

| | | | SoC | | Sensor |
|---|---|---|---|---|---|
| | Sensing | ADC | comm. | MAdds | output |
| | (pJ) | (pJ) | (pJ) | (pJ) | pixel |
| Model type | (eₚᵢₓ) | (e_{adc}) | (e_{com}) | (e_{mac}) | (Nₚᵢₓ) |
| P²M | 148 | 41.9 | 900 | 1.568 | 112 × |
| | | | | | 112 × 8 |
| Baseline (C) | 312 | 86.14 | | | 560 × |
| Baseline (NC) | | | | | 560 × 3 |

The energy values are measured for designs in 22 nm CMOS technology.
Note,
the sensing energy may include the analog convolution energy for P²M as alalog convolution is performed as a part of the sensing operation. For the e_{mac}, ther corresponding value in 45 nm is converted to that of 22 nm by following a scaling strategy.

To evaluate the delay of the models, in some embodiments a sequential execution of the layer operations is assumed and compute a single convolutional layer delay is computed using Equation 7, below, as:

$${t}_{c o n v} \approx ⌈ \frac{{( k )}^{2} {c}_{i} {c}_{0}}{( {B}_{IO} / {B}_{W} ) {N}_{bank}} ⌉ * {t}_{read} + ⌈ \frac{{( k )}^{2} {c}_{i} {c}_{0}}{{N}_{mult}} ⌉ {h}_{0} * {w}_{0} * {t}_{mult} \qquad ( 7 )$$

where the notations of the parameters and their values are shown in Table 6, below. Based on this sequential assumption, the approximate compute delay for a single forward pass for the P²M model may be given Equation 8, below, by

$${T}_{delay} \approx {T}_{sens} + {T}_{adc} + {T}_{conv} \qquad ( 8 )$$

Here, Tₛₑₙₛ and T_{adc} may correspond to the delay associated to the sensor read and ADC operation, respectively. T_{conv} may correspond to the delay associated with all the convolutional layers where each layer's delay is computed by Equation 7. Graph 850 of FIG. 8(b) shows the comparison of delay between P²M and the corresponding baselines where the total delay may be computed with the sequential sensing and SoC operation assumption. In particular, in some embodiments, the P²M approach may yield an improved delay of up to 2.15×. Thus the total EDP advantage of P²M in some embodiments may be up to 16.76×. On the other hand, even with the conservative assumption of total delay is estimated as max(Tₛₑₙₛ+T_{adc}+T_{conv}), the EDP advantage may be up to ˜11×.

TABLE 6
The description and values of the notations used for computation
of delay for some embodiments. Note, the delay is calculated in 22 nm
technology for 32-bit read and MAdd operations by applying standard
technology scaling rules to initial values in 65 nm technology. T_{read}and
T_{adc} may be directly evaluated through circuit
simulations in 22 nm technology node.

| Notation | Description | Value | |
|---|---|---|---|
| B_{IO} | I/O band-width | 64 | |
| B_{W} | Weight representation in bit-width | 32 | |
| N_{bank} | Number of memory banks | 4 | |
| Nₘᵤₗₜ | Number of multiplication units | 175 | |
| Tₛₑₙₛ | Sensor read delay | 35.84 | (P²M) |
| | | 39.2 | (baseline) |
| T_{adc} | ADC operation delay | 0.229 ms | (P²M) |
| | | 4.58 ms | (baseline) |
| tₘᵤₗₜ | Time required to perform 1 mult. | 5.48 | ns |
| | in SoC | | |
| t_{read} | Time required to perform 1 read from | 5.48 | ns |
| | SRAM in SoC | | |

Since the channels may be processed serially in the P²M approach, in some embodiments, the latency for the convolution operation may increase linearly with the number of channels. With 64 output channels, the latency of the in-pixel convolution operation may increase to 288.5 ms—from 36.1 ms with 8 channels. On the other hand, the combined sensing and first layer convolution latency using classical approach may increase only to 45.7 ms with 64 channels from 44 ms with 8 channels. This may be because the convolution delay constitutes a very small fraction of the total delay (e.g., sensing+ADC+convolution delay) in the classical approach. In some embodiments, the break-even (e.g., number of channels beyond which in-pixel convolution is slower compared to classical convolution) may happen at 10 channels. While the energy of the in-pixel convolution may increase from 0.13 mJ with 8 channels to 1.0 mJ with 32 channels, the classical convolution energy may increase from 1.31 mJ with 8 channels to 1.39 mJ with 64 channels. Hence, in some embodiments, the P²M approach may consume less energy than the classical approach even when the number of channels is increased to 64. That said, many on-device computer vision architectures (e.g., MobileNet and its variants) with tight compute and memory budgets (typical for IoT applications) have no more than 8 output channels in the first layer, which may be similar to these algorithmic findings.

With the increased availability of high-resolution image sensors, there has been a growing demand for energy-efficient on-device AI solutions. To mitigate the large amount of data transmission between the sensor and the on-device AI accelerator/processor, the Processing-in-Pixel-in-Memory (P²M) may be used which may leverage advanced CMOS technologies to enable the pixel array to perform a wider range of complex operations, including many operations required by modern convolutional neural networks (CNN) pipelines, such as multi-channel, multi-bit convolution, BN and ReLU activation. In some embodiments, only the compressed meaningful data, for example after the first few layers of custom CNN processing, is transmitted downstream to the AI processor, significantly reducing the power consumption associated with the sensor ADC and required data transmission bandwidth. As shown, experimental results for some embodiments yield reduction of data rates after the sensor ADCs by up to ˜21× compared to standard near-sensor processing solutions, significantly reducing the complexity of downstream processing. This may enable the use of relatively low-cost micro-controllers for many low-power embedded vision applications and unlocks a wide range of visual TinyML applications that require high resolution images for accuracy, but are bounded by compute and memory usage. In some embodiments, P²M may be leveraged for even more complex applications, where downstream processing can be implemented using existing near-sensor computing techniques that leverage advanced 2.5 and 3D integration technologies. None of which is to suggest that any technique suffering to some degree from these issues or other issues described in the previous paragraphs is disclaimed or that any other subject matter is disclaimed.

In another embodiment, a photo diode may be connected with a gate of an amplifying transistor, and the amplifying transistor may be connected to a set of parallel diodes where the parallel diodes may act as a source for the amplifying transistor, and where the parallel diodes may act as weighting for the output of the amplifying transistor. The parallel diodes may in turn each be controlled by one of a set of parallel input lines. Each of the parallel diodes may have different forward current capacity, such as different threshold voltage, saturation current, etc. One or more of the parallel input lines may be activated or charged at a time, which in turn may activate one or more of the parallel diodes. For example, both diode N and a diode M may be turned on during a time period, or one diode may be active at a time, or no diodes may be turned on. The total output current of the parallel diodes, which may be the source current of the sensor-gate transistor, may be the cumulative output current of those of the diodes that are selected and/or activated by the input lines. The cumulative output current may be affected by impedance and load balancing effects. The parallel diodes may have a shared output voltage, Vₒᵤₜ or V_{cathode}, and may not have shared input voltage, Vᵢₙ or V_{anode}. The output current and output voltage of the parallel diodes may be the source current and source voltage of the amplifying transistor—for example one or more of the parallel diodes may electrically contact a source region for the amplifying transistor through a conductive element, including electrical contact made through various levels of a chips such as through vias, etc. The electrical connection between an output of the parallel diodes and the source of the amplifying transistor may include other electrical elements, including capacitive elements, resistive elements, junctions between materials which may function Schottky junctions, etc. Any mention of a diode anode should be understood to also encompass examples in which the diode anode is instead a diode cathode, and any mention of a diode cathode should be understood to encompass examples in which the diode cathode is instead a diode anode, while maintaining appropriate diode characteristics and current flow directions. That is, current may flow in either direction through a diode if the diode orientation or doping is selected appropriately. In some instances, diodes may be operated in breakdown mode.

The output of the parallel diodes as gated by the amplifying transistor may be read using a word line and bit line and, optionally, a select transistor. The output of the parallel diodes may be summed, differenced, applied as a dot product, etc. The output of multiple sensors or pixels may be read in a sensor array. Multiple sensors or pixels may be connected to each of the parallel input lines, or to some of a set of input lines such that multi-channel and/or multi-kernel calculations may take place at some or all of the pixels or sensors of the sensor array. The amplifying transistor and, optionally, the select transistor enable reading of the logic and/or memory applied by the parallel diodes.

In some cases, multiple diodes or a combination of diodes and transistors may comprise the memory and/or logic instead of the single diode depicted in the figure below. Additionally, the parallel diodes may also comprise one or more diode in series and/or multiple parallel diodes electrically coupled with a single input line. For example, instead of varying forward current capacity, each input line may be connected to a varying number of similar diodes such that when an input line A is activated the output current and voltage is derived from a number A of the parallel diodes and when in input line B is activated the output current and voltage is derived from a number B of the parallel diodes. In another example, the diodes may be similar or substantially identical, but each diode may further comprise a resistor in series or parallel or other electrical element which alters the electrical output which corresponds to one or more of the input lines. Each of the input lines (e.g., the input lines P₁ through P_{N}) corresponding to different forward capacities or different numbers of diodes may correspond to an individual kernel, as previously described.

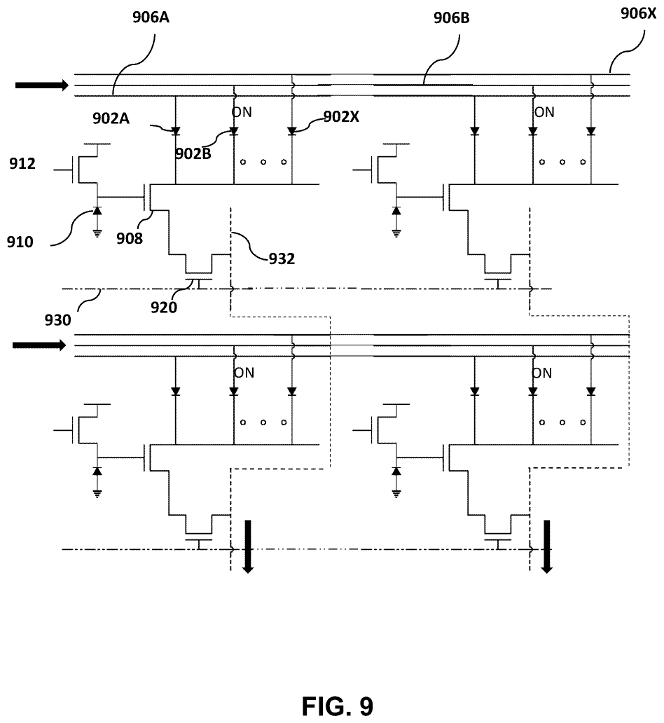

An example structure for computation using an array of pixels is depicted in FIG. 9. This structure is an array level structure for producing analog dot products. This is not the only example architecture that may be used in the sensor array but is rather only an example. Additional arrangements between pixels, including orientation of bit lines and read lines and select transistors, may be used to produce mathematical operations between the output of individual pixels such as dot product, summation, vector matrix multiplication, etc. The array level structure may also or instead include other elements of machine learning or neural network architecture, such as neural network neuron architecture.

FIG. 9 is a schematic representation of an array level structure for analog dot products using multi-bit, multi-kernels. FIG. 9 is a schematic representation of a dot product calculated using an array of multi-bit, multi-kernel ROM embedded pixels with a set of diode weighting elements. Diode weighting elements 902A, 902B, and 902X, are depicted, but more or fewer diode weighting elements 902 may make up a set of weighting elements. Each of the diode weighting elements 902 may be connected, such as in series or parallel, to a source (or drain) of an amplifying transistor 908, which may be any appropriate amplification element. Output of the set of diode weighting elements 902 functions as input to the amplifying transistor 908, such as via a source, drain, or other input. A photodiode 910, which may be any appropriate photosensor or other sensor, may be connected with a gate of the amplifying transistor 908. The photodiode 910 may be electrically connected to a reset element 912, which may be a reset transistor. Operation of the reset element 912 may be used, such as after an accumulation time, read operation, etc., to reset the photodiode 910 or the amplifying transistor 908 to a base state.

The set of diode weighting elements 902 may act as a source for the amplifying transistor 908. The diode weighting elements may in turn each be controlled by one of a set of input lines 906 (e.g., by the input lines 906A, 906B, and 906X, respectively). Each of the diode weighting elements 902 may have different physical or electrical characteristics, such as different forward current capacity, threshold voltage, saturation current, etc. One or more of the input lines 906 may be activated or charged at a time, which in turn may activate one or more of the set of diode weighting elements. For example, both a diode N and a diode M may be turned on during a time period, one diode may be active at a first time, or no diodes may be active at a second time. The total output current of the set of diode weighting elements, which may be the source current of the amplifying transistor 908, may be the cumulative output current of those of the set of diode weighting elements 902 that are selected and/or activated by the input lines 906 (e.g., input lines 906A, 906B, and 906X). The diodes may be selected in batches, such as a in a first batch corresponding to positive weightings and in a second batch corresponding to negative weightings. The cumulative output current may be affected by impedance and load balancing effects. The set of diode weighting elements 902 may have a shared output voltage, Vₒᵤₜ or V_{cathode}, and may not have shared input voltage, Vᵢₙ or V_{anode}. The output current and output voltage of the set of diode weighting elements 902 may be the source current and source voltage of the amplifying transistor 908—for example one or more of the set of diode weighting elements 902 may electrically contact a source region for the amplifying transistor 908 through a conductive element, including connected through various levels of a chips or other fabrication unit, such as through TSVs, in-plane lines, etc. The electrical connection between an output of the set of diode weighting elements 902 and the source of the amplifying transistor 908 may include other electrical elements, including capacitive elements, resistive elements, junctions between materials which may function Schottky junctions, etc. Any mention of a diode anode should be understood to also encompass examples in which the diode anode is instead a diode cathode, and any mention of a diode cathode should be understood to encompass examples in which the diode cathode is instead a diode anode, while maintaining appropriate diode characteristics and current flow. That is, current may flow in either direction through a diode if the diode orientation or doping is selected appropriately. In some instances, diodes may be operated in breakdown mode.

The output of the set of diode weighting elements 902 as switched by the amplifying transistor may be read using a word line 930 and bit line 932, including using a select transistor 920. The output of multiple sensors or pixels may be read in a sensor array. Multiple sensors or pixels (or other pixels) may be connected to each of the parallel input lines 906, or to some of a set of input lines 906 such that multi-channel and/or multi-kernel calculations may take place at some or all of the pixels or sensors of the sensor array. The amplifying transistor 908 and the select transistor 920 may enable reading of the pixel, including of any ROM (or other memory) stored in the set of diode weighting elements 902.

In some embodiments, the set of diode weighting elements 902 may comprise multiple transistors instead of single weighting diodes corresponding to each of the input lines 906. The diode weighting elements 902 may comprise one or more diode in series and/or multiple parallel diodes electrically coupled with a single input line 902. For example, instead of physical or electrical characteristic of the diode weighting elements 902, each of the set of diode weighting elements 902 may have the same electrical characteristics and each input line 906 may be connected to a varying number of diodes such that when an input line A is activated the output current and voltage is derived from a number A of the set of diode weighting elements 902 and when in input line B is activated the output current and voltage is derived from a number B of the set of diode weighting elements 902. Each of the input lines 906 (e.g., the input lines 906A-906X) corresponding to different forward currents or varying number of diodes may represent individual kernels, such as those corresponding to a given neural network layer. Thus, set of diode weighting elements 902 may function as multiple kernels for a given neural network and/or a given neural network layer. Diodes with electrical characteristics for each kernel may constitute multi-bit ROM weights for respective kernels of a given neural network layer.

In FIG. 9, the input line 906B is activated, which thereby activates (e.g., provides a forward current by) the diode weighting element 902B or each of the pixels ON. The input line 906B may correspond to a kernel. The kernel may correspond to a layer of a neural network, where the weighting of each pixel may correspond to a weight applied to the pixel in a layer of the neural network. The other input lines are not depicted as activated, which may cause the diodes weighting elements of the other diode weighting elements to operate in a low current, zero current, or negative forward current regime, or otherwise be OFF. The output of the pixels weighted by the diode weighting element 902B may be used to determine a product output, such as by measuring current output along the bit lines 932.

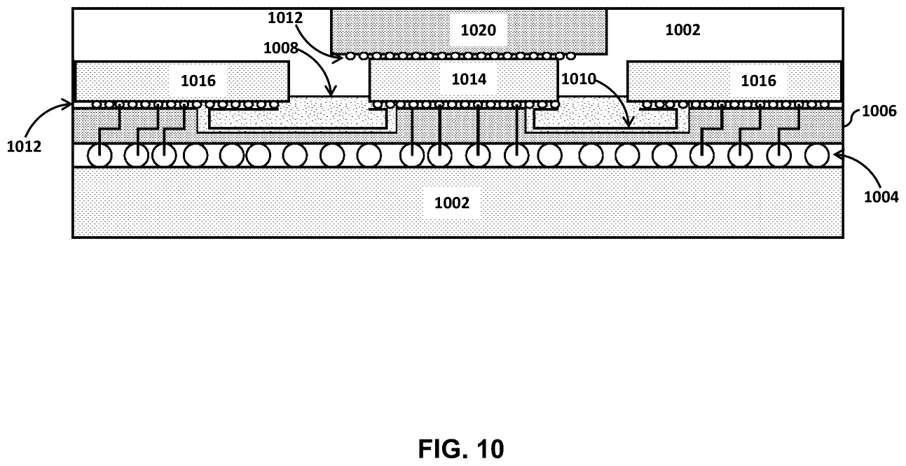

Implementation of the pixel design scheme may be either homogeneous, where the photodetector, pixel, or other sensor technology occupies the same chip or circuit substrate as memory and/or logic, or heterogeneous, where the photodetector, pixel, and/or other sensor occupy a first chip which is integrated with a second chip containing memory and/or logic. An example implementation scheme is depicted in FIG. 10. In this example, a photodetector and/or pixel layer is integrated directly with a memory chip through the use of a heterogeneous solder bump structure. Each pixel may be joined to memory (e.g., ROM, eDRAM, etc.) circuitry on the memory chip. The memory chip may then be joined to a read-out circuit (ROC), which may be or include a transimpedance amplifier (TIA), analog to digital converter (ADC), application-specific integrated circuit (ASIC), etc. The photodetector, memory, and other circuits may be joined using fan-out wafer-level packaging (FOWLP) or another appropriate packaging method. The implementation scheme may integrate three different signal and design domains, including photonic elements, analog elements, and digital elements. The implementation scheme may also include a silicon interposer or silicon layer which connects one or more other chip (or smaller chip or chiplet) including through the use of through silicon vias (TSVs). The implementation scheme may further include a printed circuit board (PCB) for connection with other electrical components such as a power supply, bus, transmitter, etc. Any layer may be connected to another layer via packaging solder bumps of appropriate size, packaging balls, pins, etc.

FIG. 10 is a schematic representation of an example integration scheme. A photodetector or pixel layer 1020, in which the photodetector and at least some of the pixel circuitry are integrated (e.g., fabricated together) is heterogeneously integrated with a memory chip 1014 through the use of a heterogeneous solder bump 1012 structure. Each pixel may be joined to memory (e.g., ROM, eDRAM, etc.) circuitry on the memory chip 1014, including to a corresponding memory element on the memory chip. Each pixel may be joined to a corresponding memory element (for example, a set of weighting elements) such as in a one-to-one relationship. For example, each pixel of the pixel layer 1020 may have an output, such as corresponding to a photodiode output which is electrically connected to an input in a unit of the memory chip 1014, such as corresponding to an input of an amplifying transistor (such as a gate) or other input. The memory chip 1014 may be divided into units, including spatially, which correspond to the pixels of the pixel layer 1020. Electrical contacts may electrically connect each pixel to a corresponding analogous unit of the memory chip 1014. For example, the memory chip 1014 may have architecture corresponding to each of the pixels, including architecture which is spaced substantially similarly to the pixel architecture. The memory chip 1014 may be organized in a manner analogous to the organization of the pixel layer 1020, including being divided into “quasi-pixels” or physical units analogous to the pixels of the pixel layer 1020 which may not contain photodetectors or other sensors. The memory chip 1014 may then be joined to a read-out circuit (ROC) 1016, which may be or include a transimpedance amplifier (TIA), analog to digital converter (ADC), application-specific integrated circuit (ASIC), etc. The pixel layer 1020, memory chip 1014, and other circuits may be joined using fan-out wafer-level packaging (FOWLP) or another appropriate packaging method. The implementation scheme may integrate three different signal and design domains, including photonic elements, analog elements, and digital elements. The implementation scheme may also include a silicon interposer or silicon layer 1006 which may connect one or more other chip (or smaller chip or chiplet) including through the use of through silicon vias (TSVs) 1010. The implementation scheme may include one or more infill layer 1008, including passivation layers, filler layers, inert layers, etc. The implementation scheme may further include a printed circuit board (PCB) 1002 for connection with other electrical components such as a power supply, bus, transmitter, etc. Any layer may be connected to another layer via packaging solder bumps 1004 of appropriate size, packaging balls, pins, etc.

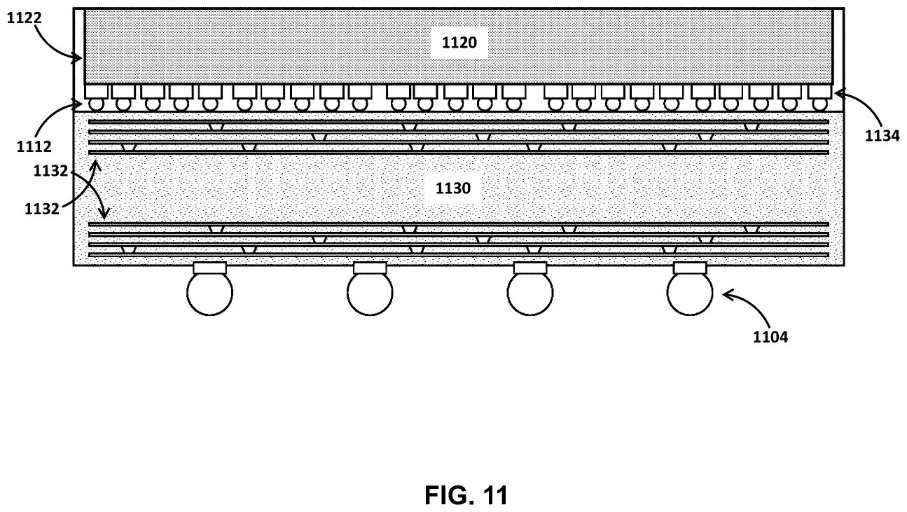

Another example implementation scheme is depicted in FIG. 11. In this example, a photodetector and/or pixel layer is homogeneously integrated with memory, ROC, and/or ASIC. In the example embodiment, the chip structure may be comprised say on 12 nm or 22 nm transistor technology. Each pixel may be joined to memory (e.g., ROM, eDRAM, etc.) circuitry which is fabricated within the photodetector chip. The memory may be fabricated in a buried layer, e.g., underneath the photosensor (or other sensor), in the area between pixels or photosensors (e.g., in waste areas), or in other areas of the chip. Likewise, the ROC and ASIC elements may also be fabricated on or from the same substrate (silicon or non-silicon substrate such as gallium arsenide (GaAs), mercury cadmium telluride (HgCdTe), etc.). One or more layers of underfill, bump metallization, and solder bumps may be used to join the homogeneously integrated pixel circuits to a packaging substrate. In some embodiments, the transistors or other elements of the pixel or sensor technology and one or more of the memory or logic technology may come from different technology nodes.

FIG. 11 is a schematic representation of an example monolithic integration scheme. Another example implementation scheme is depicted below. In this example, a photodetector and pixel layer 1120 is monolithically integrated with memory, ROC, or ASIC, which is fabricated within the photodetector and pixel layer 1120. In some embodiments, the chip structure containing the photodetector and pixel layer 1120 may be fabricated on 12 nm or 22 nm transistor technology. Each pixel may be joined to memory (e.g., ROM, eDRAM, etc.) circuitry which is fabricated within the photodetector and pixel layer 1120 or in the same chip as the photodetector and pixel layer 1120. Each pixel may contain memory circuitry within the pixel architecture (e.g., in a proximal layer of fabrication). Each pixel may be joined to memory circuitry, such as by interconnects, which are in other layers of the device. The memory may be divided into units corresponding to each of the pixels or pixel divisions. The memory may be fabrication using the same technology node as the pixel architecture, including using the same technology mode but different fabrication techniques (for example, using both FinFET technology and floating gate technology). Memory may be fabricated in a buried layer, e.g., underneath the photosensor (or other sensor), in the area between pixels or photosensors (e.g., in waste areas), or in other areas of the chip. Likewise, the ROC and ASIC elements may also be fabricated on or from the same substrate (silicon or non-silicon substrate such as gallium arsenide (GaAs), mercury cadmium telluride (HgCdTe), etc.). Each pixel may contain circuitry of the ROC or ASIC within the pixel architecture (e.g., in a proximal layer of fabrication). Each pixel may be joined to ROC or ASIC circuitry, such as by interconnects, which are in other layers of the device. The circuitry may be divided into units corresponding to each of the pixels or pixel divisions. The circuitry may be fabrication using the same technology node as the pixel architecture, including using the same technology mode but different fabrication techniques (for example, using both FinFET technology and standard FET technology). One or more layers of underfill 1122, bump metallization 1134, solder bumps 1112, and package balls 1104 may be used to join the monolithically integrated pixel circuits to a packaging substrate 1130, which may have buildup layers 1132, such as to facilitate interconnections. In some embodiments, the transistors or other elements of the pixel or sensor technology and one or more of the memory or logic technology may come from different technology nodes (for example, 12 nm and 22 nm transistor technology nodes) or come from the same node but have different fabrication architecture.

Further, heterogeneous implementation schemes may comprise one or more element of homogeneous implementation schemes. For example, pixels and memory may be integrated homogeneously, and then joined heterogeneously to logical circuitry.

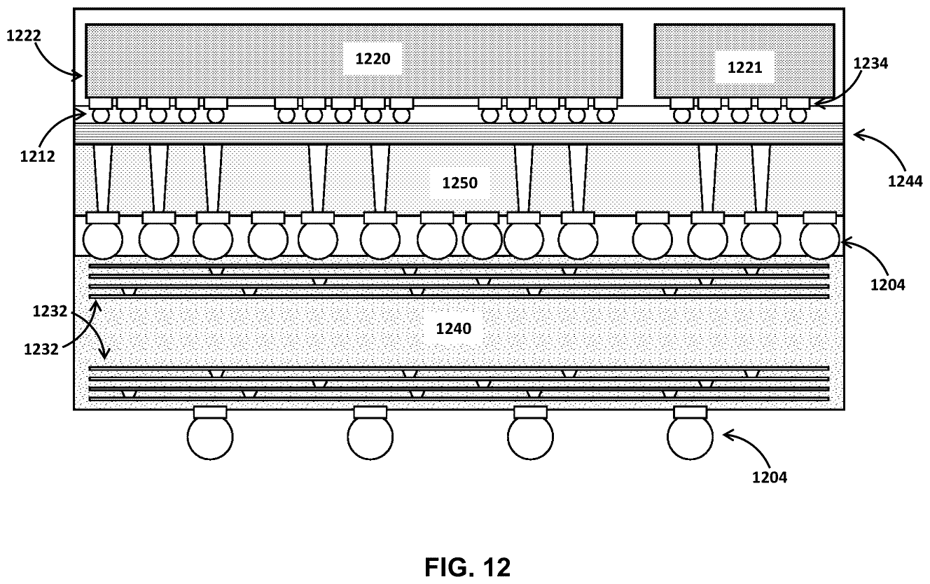

Yet another example implementation scheme is depicted in FIG. 12. In this example, a photodetector and/or pixel layer is homogeneously integrated with memory (e.g., eDRAM) and a ROC. The homogeneous sensor device is then heterogeneously integrated with a field programmable gate array (FPGA). The FPGA may instead be any other programmable logic circuitry or other logic or processor chip. The implementation scheme may include a redistribution layer (RDL) for improved access, integration, and connection between layers. One or more layers of underfill, bump metallization, and solder bumps may be used to join the circuits to a packaging substrate.

FIG. 12 is a schematic representation of an example integration scheme. A photodetector and pixel layer 1220 is monolithically integrated, including with memory (e.g., eDRAM) and a ROC. The monolithic integration of the memory with the pixel layer 1220 may include integration elements as previously described in reference to FIG. 11. The monolithic sensor device containing the photodetector and pixel layer 1220 is then heterogeneously integrated with a field programmable gate array (FPGA) 1221. The FPGA 1221 may instead be any other programmable logic circuitry or other logic or processor chip. The implementation scheme may include a redistribution layer (RDL) 1244 for improved access, integration, and connection between layers. One or more layers of underfill 1222, bump metallization 1234, solder bumps 1212, and solder balls 1204 (e.g., packaging balls) may be used to join the circuits to a packaging substrate. One or more layers may contain TSVs 1250, may have buildup layers 1232, such as to facilitate interconnections, or any other appropriate interconnection elements.

The example embodiments provide above are not an exhaustive account of those embodiments enabled by this disclosure, by the figures, or by the claims, but are shown as illustrative examples. Elements of each of the devices may be replaced by elements of other devices or combined.

Some example integration schemes are provided in Table 7, below. The technology nodes listed are not a complete list, and it should be understood that the embodiments can be practiced in a variety of technology nodes, including heterogeneous technology nodes. Pixels, memory, and/or logical elements can be implemented with technology of different nodes, even when implemented in the same material. Further, the embodiments need not be fabricated with or in silicon, either entirely or in part, and can be practiced in a heterogeneous structure including multiple materials (for example fully depleted silicon-on-insulator (FDSOI), indium gallium arsenide (InGaAs) on silicon, etc.) including those where technology nodes are less well developed.

TABLE 7
Example hardware implementation schemes,
for one or more embodiments.

| Node 1 | Node 2 | Integration |
|---|---|---|
| CMOS 180 nm pixel | 22 nm DSOI (or sub 22 nm | Heterogeneous |
| | FINFET) | |
| CMOS 65 nm pixel | 22 nm DSOI (or sub 22 nm | Heterogeneous |
| | FINFET) | |

| | |
|---|---|
| CMOS 28 nm | Monolithic |
| CMOS 22 nm | Monolithic |
| Sub 22 nm FINFET | Monolithic |

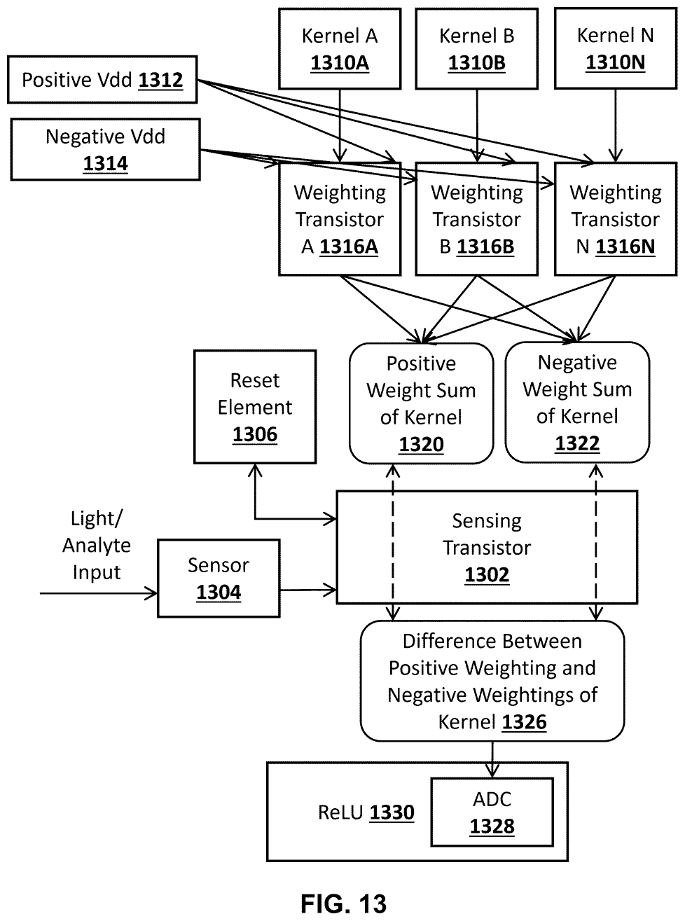

FIG. 13 is a schematic diagram that illustrates an example processing in pixel circuit. FIG. 13 depicts inputs and outputs of a sensing transistor 1302. The sensing transistor 1302 receives input (such as via a gate) from a sensor 1304. The sensor 1304 may be a photosensor, a photodiode, etc. The sensor 1304 may be integrated into the sensing transistor 1302. The sensing transistor 1304 also received input from a reset element 1306. The sensor 1304 may, for example, provide signal over a time period (e.g., an integration time). When the integration time expires, a reset signal may be provided by the reset element 1306 in order to clear a history (e.g., acquired charge) from the sensing element 1302, such as in order to initiate an additional sensing time period. The sensing transistor 1302 may instead be any appropriate circuitry, including multiple transistors, diodes, etc., and including any of the elements previously described herein.

The sensing transistor 1302 may receive input from one or more weighting elements, such as weighting transistors 1316a-1316n. The weighting transistors 1316a-1316n may provide voltage (or charge) to the sensing transistor 1302, such as to a source of the sensing transistor 1302. The weighting transistors 1316a-1316n may be in parallel, in combination of parallel and series, or in another relationship (such as those previously described). The weighting transistors 1316a-1316n may instead be other elements, such as diodes, or any appropriate circuitry. The weighting transistors 1316a-1316n may be connected to one or more kernel 1310a-1310n. The kernels 1310a-1310n may provide signals to control the weighting transistors 1316a-1316n, such as by providing voltage to gate of the weighting transistors 1316a-1316n. Each of the weighting transistors 1316a-1316n may be in communication with one or more of the kernels 1310a-1310n.

The weighting transistor 1316a-1316n may additionally in communication with a positive weighting voltage line 1312 or a negative weighting voltage line 1314. The positive weighting voltage line 1312 may correspond to a voltage line for positive weightings and may be continuously active, or cycle to be active when positive weightings are determined. Likewise, the negative weighting voltage line 1314 may correspond to a voltage line for negative weightings (and may have a positive or negative voltage value) and may be continuously active or cycle to be active when negative weightings are determined.

When a kernel (or multiple kernels) is activated, a positive weight sum of the kernel 1320 and a negative weight sum of the kernel 1322 may be applied to the sensing transistor 1302. The positive weight sum of the kernel 1320 and the negative weight sum of the kernel 1322 may be applied sequentially or simultaneous. In a case where they are applied sequentially, a difference between the output of the sensing transistor when the positive weight sum of the kernel 1320 is applied and when the negative weight sum of the kernel 1322 is applied may be determined as difference 1326. In a case where they are applied simultaneously, the positive weighting voltage line 1312 and the negative weighting voltage line 1314 may supply opposite voltages to the sensing transistor 1302 which may then output the difference 1326. The difference 1326 may be converted to a digital signal by an analog to digital converter (ADC) 1328. The ADC 1328 may output a signal to an ReLU 1330 or may be part of the ReLU 1330.

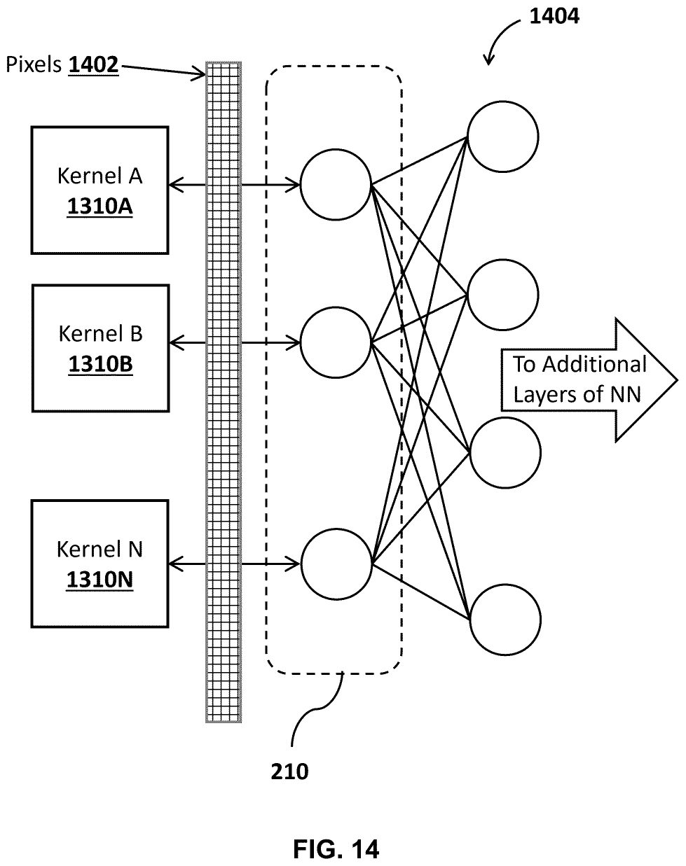

FIG. 14 is a schematic diagram that illustrates an example processing in pixel circuit in relation to a neural network. FIG. 14 depicts application of the kernels 1310a-1310n to the pixels 1402, where the kernels 1310a-1310n control output of the pixels 1402 (where output of the pixels is affected by light or other sensing application). The output of the pixels 1402 may be effected by one or more weighting elements, which are controlled by the kernels 1310a-1310n. The output of the pixels 1402 may also be processed by one or more ReLU. The output of the pixels 1402 is then fed, for example, through heterogeneous integration, into one or more layer of a neural network 1404. The processing in the pixels 1402, such as due to selection of weighting elements by the kernels 1310a-1310n, may function as one or more layer of the neural network 1404, such as as first layer 1410.

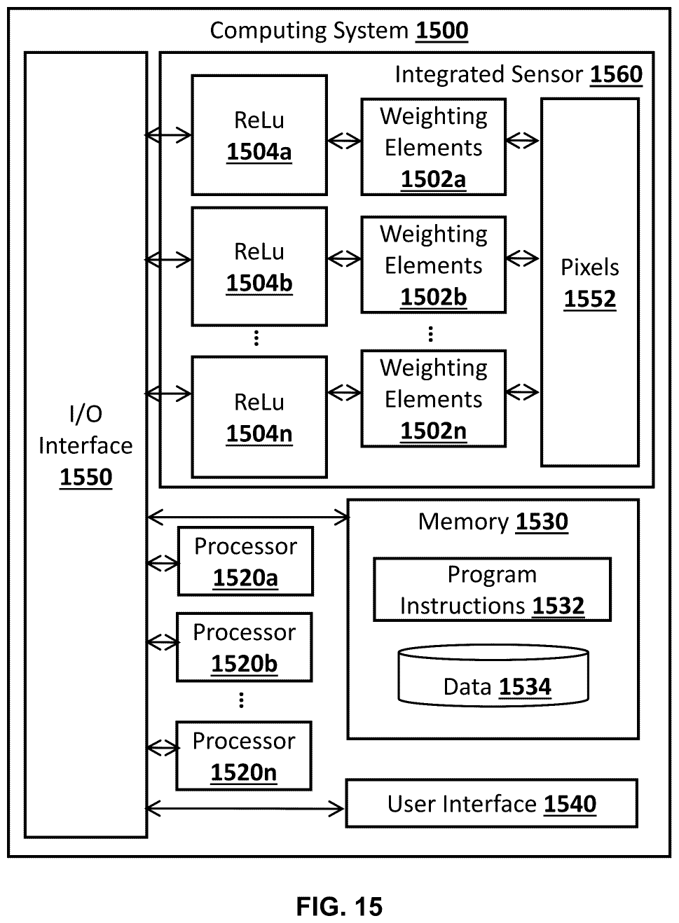

FIG. 15 is a system diagram that illustrates an example computing system comprising processing in pixel, in accordance with one or more embodiments. Various portions of systems and methods described herein may include or be executed on one or more computing systems similar to computing system 1500. Further, processes and modules described herein may be executed by one or more processing systems similar to that of computing system 1500.

Computing system 1500 may include one or more processors (e.g., processors 1520a-1520n) coupled to system memory 1530, and a user interface 1540 via an input/output (I/O) interface 1550. A processor may include a single processor or a plurality of processors (e.g., distributed processors). A processor may be any suitable processor capable of executing or otherwise performing instructions. A processor may include a central processing unit (CPU) that carries out program instructions to perform the arithmetical, logical, and input/output operations of computing system 1500. A processor may execute code (e.g., processor firmware, a protocol stack, a database management system, an operating system, or a combination thereof) that creates an execution environment for program instructions. A processor may include a programmable processor. A processor may include general or special purpose microprocessors. A processor may receive instructions and data from a memory (e.g., system memory 1530). Computing system 1500 may be a uni-processor system including one processor (e.g., processor 1520a-1520n), or a multi-processor system including any number of suitable processors (e.g., 1520a-1520n). Multiple processors may be employed to provide for parallel or sequential execution of one or more portions of the techniques described herein. Processes, such as logic flows, described herein may be performed by one or more programmable processors executing one or more computer programs to perform functions by operating on input data and generating corresponding output. Processes described herein may be performed by, and apparatus can also be implemented as, special purpose logic circuitry, e.g., an FPGA (field programmable gate array) or an ASIC (application specific integrated circuit). Computing system 1500 may include a plurality of computing devices (e.g., distributed computing systems) to implement various processing functions.

Computing system 1500 may include one or more ReLU elements (e.g., quantum ReLU 1504a-1504n), coupled to system memory 1530, and a user interface 1540 via an input/output (I/O) interface 1550. ReLU elements 1504a-1504n may also be coupled to weighting elements 1502a-1502n, respectively, and to pixels 1552. The ReLU elements 1504a-1504n may operate on outputs of the pixels 1552, which may allow transmission (e.g., pass-through) of the outputs of the weighting elements 1502a-1502n. The pixels 1552 may correspond to multiple photosensors. The pixels 1552 may instead correspond to multiple sensors. The weighting elements 1502a-1502n may be controlled by one or more kernels. The kernels may determine values of the weighting elements 1502a-1502n. The output corresponding to each of the kernels may be determined based on the values of the ReLU elements 1504a-1504n. The weighting elements 1502a-1502n may be transistors or any other appropriate elements as previously described. The ReLU elements 1504a-1504n may instead be any appropriate rectification elements, as previously described. The pixels 1552 may be connected to one or more of the weighting elements 1502a-1502n. The weighting elements 1502a-1502n may be connected to one or more of the ReLU elements 1504a-1504n, as previously described. The pixels 1552 may be controlled by one or more reset element, such as a reset element (not depicted) in communication with the I/O interface 1550 or controlled by one or more of the processors 1520a-1520n. The pixels 1552 may be exposed to input, such as light (e.g., in the case of a photosensor) or other input, an analyte (such as temperature), or other sensing material. The pixels 1552 may comprise transistors, diodes, etc.

The user interface 1540 may comprise one or more I/O device interface, for example to provide an interface for connection of one or more I/O devices to computing system 1500. The user interface 1540 may include devices that receive input (e.g., from a user) or output information (e.g., to a user). The user interface 1540 may include, for example, graphical user interface presented on displays (e.g., a cathode ray tube (CRT) or liquid crystal display (LCD) monitor), pointing devices (e.g., a computer mouse or trackball), keyboards, keypads, touchpads, scanning devices, voice recognition devices, gesture recognition devices, printers, audio speakers, microphones, cameras, or the like. The user interface 1540 may be connected to computing system 1500 through a wired or wireless connection. The user interface 1540 may be connected to computing system 1500 from a remote location. The user interface 1540 may be in communication with one or more other computing systems. Other computing units, such as located on remote computer system, for example, may be connected to computing system 800 via a network.

System memory 1530 may be configured to store program instructions 1532 or data 1534. Program instructions 1532 may be executable by a processor (e.g., one or more of processors 1520a-1520n) to implement one or more embodiments of the present techniques. Program instructions 1532 may include modules of computer program instructions for implementing one or more techniques described herein with regard to various processing modules. Program instructions may include a computer program (which in certain forms is known as a program, software, software application, script, or code). A computer program may be written in a programming language, including compiled or interpreted languages, or declarative or procedural languages. A computer program may include a unit suitable for use in a computing environment, including as a stand-alone program, a module, a component, or a subroutine. A computer program may or may not correspond to a file in a file system. A program may be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program may be deployed to be executed on one or more computer processors located locally at one site or distributed across multiple remote sites and interconnected by a communication network.

System memory 1530 may include a tangible program carrier having program instructions stored thereon. A tangible program carrier may include a non-transitory computer readable storage medium. A non-transitory computer readable storage medium may include a machine-readable storage device, a machine-readable storage substrate, a memory device, or any combination thereof. Non-transitory computer readable storage medium may include non-volatile memory (e.g., flash memory, ROM, PROM, EPROM, EEPROM memory), volatile memory (e.g., random access memory (RAM), static random-access memory (SRAM), synchronous dynamic RAM (SDRAM)), bulk storage memory (e.g., CD-ROM and/or DVD-ROM, hard-drives), or the like. System memory 1530 may include a non-transitory computer readable storage medium that may have program instructions stored thereon that are executable by a computer processor (e.g., one or more of processors 1520a-1520n) to cause the subject matter and the functional operations described herein. A memory (e.g., system memory 1530) may include a single memory device and/or a plurality of memory devices (e.g., distributed memory devices). Instructions or other program code to provide the functionality described herein may be stored on a tangible, non-transitory computer readable media. In some cases, the entire set of instructions may be stored concurrently on the media, or in some cases, different parts of the instructions may be stored on the same media at different times.

I/O interface 1550 may be configured to coordinate I/O traffic between processors 1520a-1520n, ReLU elements 1502a-1504n, system memory 1530, user interface 1540, etc. I/O interface 1550 may perform protocol, timing, or other data transformations to convert data signals from one component (e.g., system memory 1530) into a format suitable for use by another component (e.g., processors 1520a-1520n). I/O interface 1550 may include support for devices attached through various types of peripheral buses, such as a variant of the Peripheral Component Interconnect (PCI) bus standard or the Universal Serial Bus (USB) standard.

Embodiments of the techniques described herein may be implemented using a single instance of computing system 1500 or multiple computing systems 1500 configured to host different portions or instances of embodiments. Multiple computing systems 1500 may provide for parallel or sequential processing/execution of one or more portions of the techniques described herein.

Those skilled in the art will appreciate that computing system 1500 is merely illustrative and is not intended to limit the scope of the techniques described herein. Computing system 1500 may include any combination of devices or software that may perform or otherwise provide for the performance of the techniques described herein. For example, computing system 1500 may include or be a combination of a cloud-computing system, a data center, a server rack, a server, a virtual server, a desktop computer, a laptop computer, a tablet computer, a server device, a client device, a mobile telephone, a personal digital assistant (PDA), a mobile audio or video player, a game console, a vehicle-mounted computer, or a Global Positioning System (GPS), or the like. Computing system 1500 may also be connected to other devices that are not illustrated, or may operate as a stand-alone system. In addition, the functionality provided by the illustrated components may in some embodiments be combined in fewer components or distributed in additional components. Similarly, in some embodiments, the functionality of some of the illustrated components may not be provided or other additional functionality may be available.

Those skilled in the art will also appreciate that while various items are illustrated as being stored in memory or on storage while being used, these items or portions of them may be transferred between memory and other storage devices for purposes of memory management and data integrity. Alternatively, in other embodiments some or all of the software components may execute in memory on another device and communicate with the illustrated computer system via inter-computer communication. Some or all of the system components or data structures may also be stored (e.g., as instructions or structured data) on a computer-accessible medium or a portable article to be read by an appropriate drive, various examples of which are described above. In some embodiments, instructions stored on a computer-accessible medium separate from computing system 1500 may be transmitted to computing system 1500 via transmission media or signals such as electrical, electromagnetic, or digital signals, conveyed via a communication medium such as a network or a wireless link. Various embodiments may further include receiving, sending, or storing instructions or data implemented in accordance with the foregoing description upon a computer-accessible medium. Accordingly, the present techniques may be practiced with other computer system configurations.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g., within a data center or geographically), or otherwise differently organized. The functionality described herein may be provided by one or more processors of one or more computers executing code stored on a tangible, non-transitory, machine-readable medium. In some cases, third party content delivery networks may host some or all of the information conveyed over networks, in which case, to the extent information (e.g., content) is said to be supplied or otherwise provided, the information may be provided by sending instructions to retrieve that information from a content delivery network.

The reader should appreciate that the present application describes several disclosures. Rather than separating those disclosures into multiple isolated patent applications, applicants have grouped these disclosures into a single document because their related subject matter lends itself to economies in the application process. But the distinct advantages and aspects of such disclosures should not be conflated. In some cases, embodiments address all of the deficiencies noted herein, but it should be understood that the disclosures are independently useful, and some embodiments address only a subset of such problems or offer other, unmentioned benefits that will be apparent to those of skill in the art reviewing the present disclosure. Due to costs constraints, some features disclosed herein may not be presently claimed and may be claimed in later filings, such as continuation applications or by amending the present claims. Similarly, due to space constraints, neither the Abstract nor the Summary sections of the present document should be taken as containing a comprehensive listing of all such disclosures or all aspects of such disclosures.

It should be understood that the description and the drawings are not intended to limit the disclosure to the particular form disclosed, but to the contrary, the intention is to cover all modifications, equivalents, and alternatives falling within the spirit and scope of the present disclosure as defined by the appended claims. Further modifications and alternative embodiments of various aspects of the disclosure will be apparent to those skilled in the art in view of this description. Accordingly, this description and the drawings are to be construed as illustrative only and are for the purpose of teaching those skilled in the art the general manner of carrying out the disclosure. It is to be understood that the forms of the disclosure shown and described herein are to be taken as examples of embodiments. Elements and materials may be substituted for those illustrated and described herein, parts and processes may be reversed or omitted, and certain features of the disclosure may be utilized independently, all as would be apparent to one skilled in the art after having the benefit of this description of the disclosure. Changes may be made in the elements described herein without departing from the spirit and scope of the disclosure as described in the following claims. Headings used herein are for organizational purposes only and are not meant to be used to limit the scope of the description.

As used throughout this application, the word “may” is used in a permissive sense (e.g., meaning having the potential to), rather than the mandatory sense (e.g., meaning must). The words “include”, “including”, and “includes” and the like mean including, but not limited to. As used throughout this application, the singular forms “a,” “an,” and “the” include plural referents unless the content explicitly indicates otherwise. Thus, for example, reference to “an element” or “a element” includes a combination of two or more elements, notwithstanding use of other terms and phrases for one or more elements, such as “one or more.” The term “or” is, unless indicated otherwise, non-exclusive, e.g., encompassing both “and” and “or.” Terms describing conditional relationships, e.g., “in response to X, Y,” “upon X, Y,”, “if X, Y,” “when X, Y,” and the like, encompass causal relationships in which the antecedent is a necessary causal condition, the antecedent is a sufficient causal condition, or the antecedent is a contributory causal condition of the consequent, e.g., “state X occurs upon condition Y obtaining” is generic to “X occurs solely upon Y” and “X occurs upon Y and Z.” Such conditional relationships are not limited to consequences that instantly follow the antecedent obtaining, as some consequences may be delayed, and in conditional statements, antecedents are connected to their consequents, e.g., the antecedent is relevant to the likelihood of the consequent occurring. Statements in which a plurality of attributes or functions are mapped to a plurality of objects (e.g., one or more processors performing steps A, B, C, and D) encompasses both all such attributes or functions being mapped to all such objects and subsets of the attributes or functions being mapped to subsets of the attributes or functions (e.g., both all processors each performing steps A-D, and a case in which processor 1 performs step A, processor 2 performs step B and part of step C, and processor 3 performs part of step C and step D), unless otherwise indicated. Similarly, reference to “a computer system” performing step A and “the computer system” performing step B can include the same computing device within the computer system performing both steps or different computing devices within the computer system performing steps A and B. Further, unless otherwise indicated, statements that one value or action is “based on” another condition or value encompass both instances in which the condition or value is the sole factor and instances in which the condition or value is one factor among a plurality of factors. Unless otherwise indicated, statements that “each” instance of some collection have some property should not be read to exclude cases where some otherwise identical or similar members of a larger collection do not have the property, e.g., each does not necessarily mean each and every. Limitations as to sequence of recited steps should not be read into the claims unless explicitly specified, e.g., with explicit language like “after performing X, performing Y,” in contrast to statements that might be improperly argued to imply sequence limitations, like “performing X on items, performing Y on the X'ed items,” used for purposes of making claims more readable rather than specifying sequence. Statements referring to “at least Z of A, B, and C,” and the like (e.g., “at least Z of A, B, or C”), refer to at least Z of the listed categories (A, B, and C) and do not require at least Z units in each category. Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device. Features described with reference to geometric constructs, like “parallel,” “perpendicular/orthogonal,” “square”, “cylindrical,” and the like, should be construed as encompassing items that substantially embody the properties of the geometric construct, e.g., reference to “parallel” surfaces encompasses substantially parallel surfaces. The permitted range of deviation from Platonic ideals of these geometric constructs is to be determined with reference to ranges in the specification, and where such ranges are not stated, with reference to industry norms in the field of use, and where such ranges are not defined, with reference to industry norms in the field of manufacturing of the designated feature, and where such ranges are not defined, features substantially embodying a geometric construct should be construed to include those features within 15% of the defining attributes of that geometric construct. The terms “first”, “second”, “third,” “given” and so on, if used in the claims, are used to distinguish or otherwise identify, and not to show a sequential or numerical limitation. As is the case in ordinary usage in the field, data structures and formats described with reference to uses salient to a human need not be presented in a human-intelligible format to constitute the described data structure or format, e.g., text need not be rendered or even encoded in Unicode or ASCII to constitute text; images, maps, and data-visualizations need not be displayed or decoded to constitute images, maps, and data-visualizations, respectively; speech, music, and other audio need not be emitted through a speaker or decoded to constitute speech, music, or other audio, respectively. Computer implemented instructions, commands, and the like are not limited to executable code and can be implemented in the form of data that causes functionality to be invoked, e.g., in the form of arguments of a function or API call. To the extent bespoke noun phrases (and other coined terms) are used in the claims and lack a self-evident construction, the definition of such phrases may be recited in the claim itself, in which case, the use of such bespoke noun phrases should not be taken as invitation to impart additional limitations by looking to the specification or extrinsic evidence.

The above-described embodiments of the present disclosure are presented for purposes of illustration and not of limitation, and the present disclosure is limited only by the claims which follow. Furthermore, it should be noted that the features and limitations described in any one embodiment may be applied to any other embodiment herein, and flowcharts or examples relating to one embodiment may be combined with any other embodiment in a suitable manner, done in different orders, or done in parallel. In addition, the systems and methods described herein may be performed in real time. It should also be noted that the systems and/or methods described above may be applied to, or used in accordance with, other systems and/or methods.

In this patent filing, to the extent any U.S. patents, U.S. patent applications, or other materials (e.g., articles) have been incorporated by reference, the text of such materials is only incorporated by reference to the extent that no conflict exists between such material and the statements and drawings set forth herein. In the event of such conflict, the text of the present document governs, and terms in this document should not be given a narrower reading in virtue of the way in which those terms are used in other materials incorporated by reference.

The present techniques may be better understood with reference to the following enumerated embodiments:
1. An integrated circuit comprising: a sensor structure; a set of weighting elements, each configured to weight an output of the sensor structure; and an output element, the output element configured to collect weighted outputs of the set of weighting elements.
2. The integrated circuit of embodiment 1, wherein the sensor structure comprises a sensor.
3. The integrated circuit of embodiment 2, wherein the sensor is a photodiode.
4. The integrated circuit of embodiment 2, wherein the sensor is a photosensor.
5. The integrated circuit of embodiment 2, wherein the sensor is an infrared sensor.
6. The integrated circuit of embodiment 2, wherein the sensor is a terahertz sensor.
7. The integrated circuit of embodiment 2, wherein the sensor structure further comprises a memory structure.
8. The integrated circuit of embodiment 2, wherein the sensor structure further comprises a reset element.
9. The integrated circuit of embodiment 2, wherein the sensor structure further comprises an amplifying transistor.
10. The integrated circuit of embodiment 9, wherein the sensor structure is electrically connected with a gate of the amplifying transistor.
11. The integrated circuit of embodiment 1, wherein the set of weighting elements comprises a set of weighting transistors.
12. The integrated circuit of embodiment 11, wherein the set of weighting transistors comprises transistors of varying widths.
13. The integrated circuit of embodiment 11, wherein the set of weighting transistors comprises transistors of varying W/L.
14. The integrated circuit of embodiment 11, wherein each of the set of weighting transistors is configured to be selected by one or more of a set of select lines.
15. The integrated circuit of embodiment 14, wherein selecting one of the set of weighting transistors comprises turning the one of the set of weighting transistors on.
16. The integrated circuit of embodiment 14, wherein each of the set of select lines corresponds to a kernel.
17. The integrated circuit of embodiment 11, wherein each of the set of weighting transistors is configured to supply a corresponding voltage to an input the sensor structure, the sensor structure configured to provide an output based on inputs from the set of weighting transistors.
18. The integrated circuit of embodiment 11, wherein each of the set of weighting transistors is configured to receive an input voltage from a supply voltage.
19. The integrated circuit of embodiment 17, wherein the set of weighting transistors is configured to receive a supply voltage from a supply voltage line for positive weights and/or a supply voltage line for negative weights.
20. The integrated circuit of embodiment 11, wherein the set of weighting transistors comprises a set of weighting transistors each configured to apply a weighting based on a stored weighting value.
21. The integrated circuit of embodiment 20, wherein the stored weighting value is fixed.
22. The integrated circuit of embodiment 20, wherein the stored weighting value is configured to be changed.
23. The integrated circuit of embodiment 20, wherein the stored weighting value corresponds to a weighting value for a layer of a machine learning model.
24. The integrated circuit of embodiment 23, wherein the machine learning model is a convolutional neural network.
25. The integrated circuit of embodiment 1, wherein the output element is further configured to perform a computational processes.
26. The integrated circuit of embodiment 1, comprising at least one PMOS transistor.
27. The integrated circuit of embodiment 1, wherein the sensor structure comprises a pixel.
28. The integrated circuit of embodiment 1, further comprising homogeneous integration.
29. The integrated circuit of embodiment 1, further comprising heterogeneous integration.
30. The integrated circuit of embodiment 1, further comprising an analog to digital converter (ADC).
31. The integrated circuit of embodiment 1, further comprising a single-slope ADC.
32. The integrated circuit of embodiment 1, further comprising a latched output element configured to rectify one or more output.
33. An integrated circuit structure comprising:
an array of cells, wherein each cell comprises at least a first integrated circuit of any one of embodiments 1 to 32.
34. The integrated circuit structure of embodiment 33, further comprising a convolution output element configured to collect weighted outputs of the set of weighting elements of one or more of the cells.
35. The integrated circuit structure of embodiment 34, wherein the convolution output element is further configured to convolve the weighted outputs of the set of weighting elements of one or more of the cells.
36. The integrated circuit structure of embodiment 35, wherein the convolution output element is configured to collect weighted outputs of the set of weighting elements corresponding to positive weights and weighted outputs of the set of weighting elements corresponding to negative weights.
37. The integrated circuit structure of embodiment 36, wherein the convolution output element is configured to determine a difference between the weighted outputs of the set of weighting elements corresponding to positive weights and the weighted outputs of the set of weighting elements corresponding to negative weights.
38. The integrated circuit structure of embodiment 37, wherein the convolution output element is configured to rectify the difference between the weighted outputs of the set of weighting elements corresponding to positive weights and the weighted outputs of the set of weighting elements corresponding to negative weights.
39. The integrated circuit structure of embodiment 35, wherein the convolution output element comprises a rectification linear unit.
40. The integrated circuit structure of embodiment 33, further comprising multiple kernels.
41. A method of fabricating the integrated circuit of any one of embodiments 1 to 32.
42. A method of fabricating the integrated circuit structure of any one of embodiments 33 to 40.

1. An integrated circuit comprising:
a sensor structure;
a set of weighting elements, each configured to weight an output of the sensor structure; and
an output element, the output element configured to collect weighted outputs of the set of weighting elements.

2. The integrated circuit of claim 1, wherein the sensor structure comprises a sensor and the sensor is at least one of the following: photodiode, a photosensor, an infrared sensor, and a terahertz sensor.

3. The integrated circuit of claim 2, wherein the sensor structure further comprises at least one of the following: a pixel, a memory structure, a reset element, and an amplifying transistor.

4. The integrated circuit of claim 3, wherein the sensor structure is electrically connected with a gate of the amplifying transistor.

5. The integrated circuit of claim 1, wherein the set of weighting elements comprises a set of weighting transistors, the set of weighting transistors comprising transistors or varying widths and/or varying W/Ls.

6. The integrated circuit of claim 5, wherein each of the set of weighting transistors is configured to be selected by one or more of a set of select lines.

7. The integrated circuit of claim 6, wherein each of the set of select lines corresponds to a kernel.

8. The integrated circuit of claim 5, wherein each of the set of weighting transistors is configured to receive a supply voltage from a supply voltage line for positive weights and/or a supply voltage line for negative weights.

9. The integrated circuit of claim 5, wherein the set of weighting transistors comprises a set of weighting transistors each configured to apply a weighting based on a stored weighting value.

10. The integrated circuit of claim 9, wherein the stored weighting value is fixed and/or configured to be changed.

11. The integrated circuit of claim 9, wherein the stored weighting value corresponds to a weighting value for a layer of a machine learning model.

12. The integrated circuit of claim 11, wherein the machine learning model is a convolutional neural network.

13. The integrated circuit of claim 1, comprising at least one PMOS transistor.

14. The integrated circuit of claim 1, further comprising homogeneous integration and/or heterogeneous integration.

15. The integrated circuit of claim 1, further comprising an analog to digital converter (ADC).

16. The integrated circuit of claim 1, further comprising a single-slope ADC.

17. The integrated circuit of claim 1, further comprising a latched output element configured to rectify one or more output.

18. An integrated circuit structure comprising:
an array of cells, each cell comprising:
a sensor structure;
a set of weighting elements, each configured to weight an output of the sensor structure; and
an output element, the output element configured to collect weighted outputs of the set of weighting elements.

19. The array of claim 18, wherein the sensor structure comprises a sensor and the sensor is at least one of the following: photodiode, a photosensor, an infrared sensor, and a terahertz sensor.

20. The array of claim 18, further comprising an accumulation node configured to accumulate charge and/or voltage from multiple of the cells of the array.
